(19) United States
(12) Patent Application Publication
(10) Pub. No.: US 2025/0294753 A1
(43) Pub. Date: Sep. 18, 2025

(54) SEMICONDUCTOR MEMORY DEVICE

(71) Applicant: Kioxia Corporation, Tokyo (JP)

(72) Inventors: Satoshi Nagashima, Yokkaichi Mie (JP); Shota Kashiyama, Mie Mie (JP)

(73) Assignee: Kioxia Corporation, Tokyo (JP)

(21) Appl. No.: 18/981,076

(22) Filed: Dec. 13, 2024

(30) Foreign Application Priority Data
Mar. 18, 2024 (JP) 2024-042763

(51) Int. Cl. H10B 43/27; H10B 41/10; H10B 41/27; H10B 43/10

(52) U.S. Cl. CPC H10B 43/27; H10B 41/10; H10B 41/27; H10B 43/10

(57) ABSTRACT

According to one embodiment, a memory system includes a first semiconductor layer, a plurality of first interconnect layers, a plurality of second interconnect layers, a third interconnect layer, a third memory pillar including a first memory pillar and a second memory pillar, a first support pillar passing through the plurality of first interconnect layers in a first region, a second support pillar passing through at least the plurality of second interconnect layers and the third interconnect layer in a first region, a third support pillar passing through at least one of the plurality of first interconnect layers and having a larger diameter than the first support pillar and the second support pillar in the second region, and a fourth support pillar provided on the third support pillar and having a larger diameter than the first support pillar and the second support pillar in the second region.

### CROSS-REFERENCE TO RELATED APPLICATIONS

This application is based upon and claims the benefit of priority from prior Japanese Patent Application No. 2024-042763, filed Mar. 18, 2024, the entire contents of which are incorporated herein by reference.

### FIELD

Embodiments described herein relate generally to a semiconductor memory device.

### BACKGROUND

A NAND-type flash memory is known as one of the semiconductor memory devices.

### BRIEF DESCRIPTION OF THE DRAWINGS

FIG. 1 is a block diagram showing an example of an overall configuration of a semiconductor memory device according to a first embodiment.

FIG. 2 is a circuit diagram of a memory cell array included in the semiconductor memory device according to the first embodiment.

FIG. 3 is a plan view showing an example of a planar layout of the memory cell array in the semiconductor memory device according to the first embodiment.

FIG. 4 is an enlarged view of a region ER in FIG. 3.

FIG. 5 is a cross-sectional view of the memory cell array taken along line XI-XI in FIG. 4.

FIG. 6 is a cross-sectional view of the memory cell array taken along line XII-XII in FIG. 4.

FIG. 7 is a cross-sectional view of a memory pillar in an XY plane taken along line VI-VI in FIG. 6.

FIG. 8 is a plan view of the memory cell array showing a manufacturing process of the memory cell array in the semiconductor memory device according to the first embodiment.

FIG. 9 is a cross-sectional view of the memory cell array showing a manufacturing process of the memory cell array in the semiconductor memory device according to the first embodiment.

FIG. 10 is a plan view of the memory cell array showing a manufacturing process of the memory cell array in the semiconductor memory device according to the first embodiment.

FIG. 11 is a cross-sectional view of the memory cell array showing a manufacturing process of the memory cell array in the semiconductor memory device according to the first embodiment.

FIG. 12 is a plan view of the memory cell array showing a manufacturing process of the memory cell array in the semiconductor memory device according to the first embodiment.

FIG. 13 is a cross-sectional view of the memory cell array showing a manufacturing process of the memory cell array in the semiconductor memory device according to the first embodiment.

FIG. 14 is a plan view of the memory cell array showing a manufacturing process of the memory cell array in the semiconductor memory device according to the first embodiment.

FIG. 15 is a cross-sectional view of the memory cell array showing a manufacturing process of the memory cell array in the semiconductor memory device according to the first embodiment.

FIG. 16 is a plan view of the memory cell array showing a manufacturing process of the memory cell array in the semiconductor memory device according to the first embodiment.

FIG. 17 is a cross-sectional view of the memory cell array showing a manufacturing process of the memory cell array in the semiconductor memory device according to the first embodiment.

FIG. 18 is a plan view of the memory cell array showing a manufacturing process of the memory cell array in the semiconductor memory device according to the first embodiment.

FIG. 19 is a cross-sectional view of the memory cell array showing a manufacturing process of the memory cell array in the semiconductor memory device according to the first embodiment.

FIG. 20 is a plan view of the memory cell array showing a manufacturing process of the memory cell array in the semiconductor memory device according to the first embodiment.

FIG. 21 is a cross-sectional view of the memory cell array showing a manufacturing process of the memory cell array in the semiconductor memory device according to the first embodiment.

FIG. 22 is a plan view of the memory cell array showing a manufacturing process of the memory cell array in the semiconductor memory device according to the first embodiment.

FIG. 23 is a cross-sectional view of the memory cell array showing a manufacturing process of the memory cell array in the semiconductor memory device according to the first embodiment.

FIG. 24 is a plan view of the memory cell array showing a manufacturing process of the memory cell array in the semiconductor memory device according to the first embodiment.

FIG. 25 is a cross-sectional view of the memory cell array showing a manufacturing process of the memory cell array in the semiconductor memory device according to the first embodiment.

FIG. 26 is a plan view of the memory cell array showing a manufacturing process of the memory cell array in the semiconductor memory device according to the first embodiment.

FIG. 27 is a cross-sectional view of the memory cell array showing a manufacturing process of the memory cell array in the semiconductor memory device according to the first embodiment.

FIG. 28 is a plan view of the memory cell array showing a manufacturing process of the memory cell array in the semiconductor memory device according to the first embodiment.

FIG. 29 is a cross-sectional view of the memory cell array showing a manufacturing process of the memory cell array in the semiconductor memory device according to the first embodiment.

FIG. 30 is a plan view of the memory cell array showing a manufacturing process of the memory cell array in the semiconductor memory device according to the first embodiment.

FIG. 31 is a cross-sectional view of the memory cell array showing a manufacturing process of the memory cell array in the semiconductor memory device according to the first embodiment.

FIG. 32 is a plan view of the memory cell array showing a manufacturing process of the memory cell array in the semiconductor memory device according to the first embodiment.

FIG. 33 is a cross-sectional view of the memory cell array showing a manufacturing process of the memory cell array in the semiconductor memory device according to the first embodiment.

FIG. 34 is a plan view of the memory cell array showing a manufacturing process of the memory cell array in the semiconductor memory device according to the first embodiment.

FIG. 35 is a cross-sectional view of the memory cell array showing a manufacturing process of the memory cell array in the semiconductor memory device according to the first embodiment.

FIG. 36 is a plan view showing an example of a planar layout of the memory cell array in the semiconductor memory device according to a second embodiment.

FIG. 37 is a cross-sectional view of the memory cell array taken along line XI-XI in FIG. 36.

FIG. 38 is a plan view of the memory cell array showing a manufacturing process of the memory cell array in the semiconductor memory device according to the second embodiment.

FIG. 39 is a cross-sectional view of the memory cell array showing a manufacturing process of the memory cell array in the semiconductor memory device according to the second embodiment.

FIG. 40 is a plan view of the memory cell array showing a manufacturing process of the memory cell array in the semiconductor memory device according to the second embodiment.

FIG. 41 is a cross-sectional view of the memory cell array showing a manufacturing process of the memory cell array in the semiconductor memory device according to the second embodiment.

FIG. 42 is a plan view showing an example of a planar layout of a memory cell array in a semiconductor memory device according to a third embodiment.

FIG. 43 is a cross-sectional view of the memory cell array taken along line XI-XI in FIG. 42.

### DETAILED DESCRIPTION

In general, according to one embodiment, a semiconductor memory device includes a first semiconductor layer provided above a substrate, a plurality of first interconnect layers stacked apart from each other in a first direction above the first semiconductor layer, a plurality of second interconnect layers stacked and separated from each other in the first direction above the plurality of first interconnect layers, a third interconnect layer provided above the plurality of second interconnect layers, a third memory pillar including a first memory pillar passing through the plurality of first interconnect layers in the first direction and a second memory pillar provided on the first memory pillar and passing through the plurality of second interconnect layers and the third interconnect layer in the first direction, a first region where a first contact plug is provided on the third interconnect layer, a second region where a second contact plug is provided on each of the plurality of second interconnect layers, a first support pillar passing through the plurality of first interconnect layers in the first region, a second support pillar passing through at least the plurality of second interconnect layers and the third interconnect layer in the first region, a third support pillar passing through at least one of the plurality of first interconnect layers and having a larger diameter than the first support pillar and the second support pillar in the second region, and a fourth support pillar provided on the third support pillar and having a larger diameter than the first support pillar and the second support pillar in the second region.

Embodiments will be described below with reference to the accompanying drawings. In the following description, constituent elements having the same functions and configurations are denoted by common reference numerals. In addition, a plurality of constituent elements having common reference numerals are distinguished by adding suffixes to the common reference numerals. Note that if there is no need to distinguish a plurality of constituent elements, the plurality of constituent elements are denoted by only common reference numerals without adding any suffixes. In this case, suffixes are not limited to subscripts and superscripts and include, for example, lowercase alphabets and indices meaning arrays added to the ends of reference numerals.

### 1. First Embodiment

A semiconductor memory device 1 according to the first embodiment will be described. The following will exemplify, as the semiconductor memory device 1, a three-dimensionally stacked NAND-type flash memory having memory cell transistors three-dimensionally stacked on a semiconductor substrate.

### 1.1 Overall Configuration of Semiconductor Memory Device

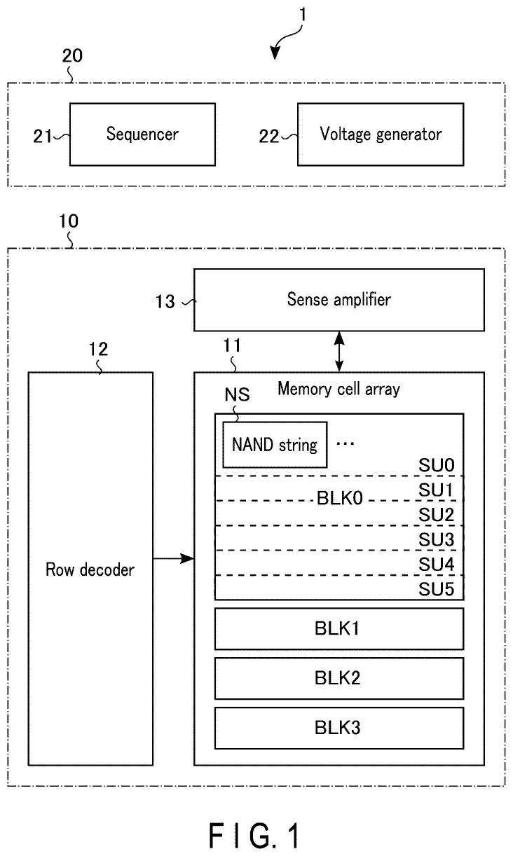

An example of the overall configuration of the semiconductor memory device 1 will be described first with reference to FIG. 1. FIG. 1 is a block diagram showing an example of the overall configuration of the semiconductor memory device 1. Although the arrow lines indicate parts of the couplings of the respective constituent elements in FIG. 1, the couplings between the constituent elements are not limited to them.

As shown in FIG. 1, the semiconductor memory device 1 includes a memory core unit 10 and a peripheral circuit unit 20.

The memory core unit 10 includes a memory cell array 11, a row decoder 12, and a sense amplifier 13.

The memory cell array 11 is a region where nonvolatile memory cell transistors are three-dimensionally arranged. The memory cell array 11 includes a plurality of blocks BLK. In the example shown in FIG. 1, the memory cell array 11 includes four blocks BLK0 to BLK3. Each block BLK is, for example, a set of a plurality of memory cell transistors whose data are collectively erased. The block BLK includes a plurality of memory cell transistors associated with rows and columns. The block BLK includes a plurality of string units SU. In the example shown in FIG. 1, the block BLK includes six string units SU0, SU1, SU2, SU3, SU4, and SU5. Each string unit SU includes a set of a plurality of NAND strings NS collectively selected in a write operation or a read operation. Each NAND string NS includes a set of a plurality of memory cell transistors coupled in series. Note that the number of blocks BLK in the memory cell array 11 and the number of string units SU in the block BLK are arbitrary. The memory cell array 11 will be described in detail later.

The row decoder 12 is a circuit that decodes row address. The row decoder 12 receives a row address input from an external controller. The row decoder 12 selects interconnects (a word line and a selection gate (to be described later)) in the row direction of the memory cell array 11 based on the decoding result of the row address. The row decoder 12 supplies voltages to the selected Interconnects in the row direction.

The sense amplifier 13 is a circuit that writes and reads data. The sense amplifier 13 reads data from the memory cell transistors of any one of the blocks BLK in the read operation. In addition, the sense amplifier 13 supplies voltages based on write data to the memory cell array 11 in the write operation.

A peripheral circuit unit 20 includes a sequencer 21 and a voltage generator 22.

The sequencer 21 controls an overall operation of the semiconductor memory device 1. More specifically, the sequencer 21 controls the voltage generator 22, the row decoder 12, the sense amplifier 13, and the like in the write operation, the read operation, or an erase operation.

The voltage generator 22 generates voltages used for the write operation, the read operation, or the erase operation and supplies the voltages to the row decoder 12, the sense amplifier 13, and the like.

### 1.2 Circuit Configuration of Memory Cell Array

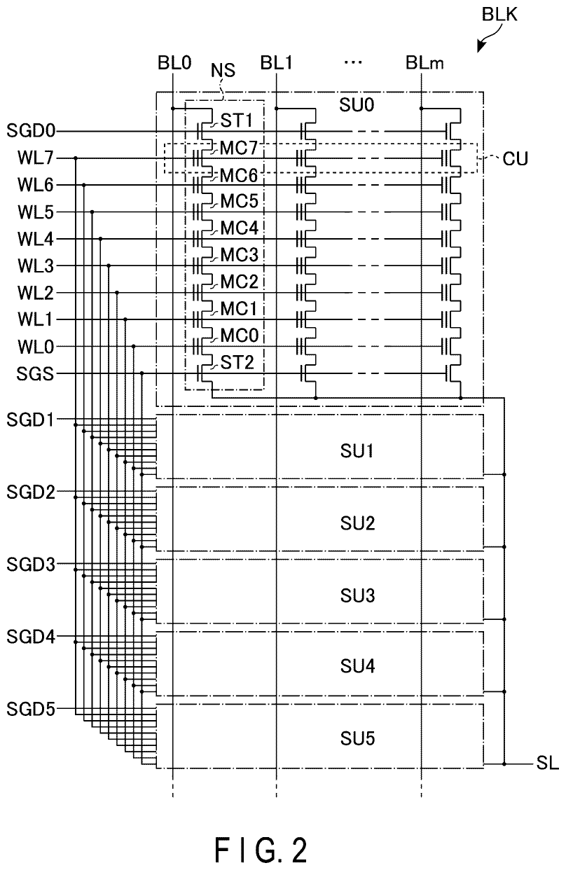

An example of a circuit configuration of the memory cell array 11 will be described next with reference to FIG. 2. FIG. 2 is a circuit diagram of the memory cell array 11. Note that the example shown in FIG. 2 indicates one block BLK, and the other blocks BLK also have the same configuration.

The block BLK includes, for example, the six string units SU0 to SU5. Note that the number of string units SU included in the block BLK is arbitrary. The string units SU are, for example, a set of a plurality of NAND strings NS collectively selected in the write operation or the read operation.

An internal configuration of each string unit SU will be described next. The string unit SU includes a plurality of NAND strings NS. Each NAND string NS is a set of a plurality of memory cell transistors coupled in series. Each of the plurality of NAND strings NS in the string unit SU is coupled to a corresponding one of bit lines BL0 to BLm (m is an integer equal to or more than 1).

An internal configuration of the NAND string NS will be described next. Each NAND string NS includes a plurality of memory cell transistors MC, one or more selection transistors ST1, and one or more selection transistors ST2. In the example shown in FIG. 2, the NAND string NS includes eight memory cell transistors MC0 to MC7, the one selection transistor ST1, and the one selection transistor ST2.

The memory cell transistor MC is a memory element that stores data in a nonvolatile manner. The memory cell transistor MC includes a control gate and a charge storage film. The memory cell transistor MC may be of a metal-oxide-nitride-oxide-silicon (MONOS) using an insulator as the charge storage film or a floating gate (FG) type using a conductor as the charge storage film. Hereinafter, a case where the memory cell MC is of the MONOS type will be described.

The selection transistors ST1 and ST2 are switching elements. The selection transistors ST1 and ST2 each are used for the selection of the string unit SU at the time of each operation.

The current paths of the selection transistor ST2, the memory cell transistors MC0 to MC7, and the selection transistor ST1 in the NAND string NS are coupled in series. A drain of the selection transistor ST1 is coupled to the bit line BL. A source of the selection transistor ST2 is coupled to a source line SL.

Control gates of the memory cell transistors MC0 to MC7 of the same block BLK are respectively and commonly coupled to word lines WL0 to WL7. More specifically, for example, the block BLK includes the six string units SU0 to SU5. Each string unit SU includes a plurality of memory cell transistors MC0. The control gates of the plurality of memory cell transistors MC0 in the block BLK are commonly coupled to one word line WL0. The same applies to the memory cell transistors MC1 to MC7.

Gates of the plurality of selection transistors ST1 in the string unit SU are commonly coupled to one select gate line SGD. More specifically, gates of the plurality of selection transistors ST1 in the string unit SU0 are commonly coupled to a select gate line SGD0. Gates of the plurality of selection transistors ST1 in the string unit SU1 are commonly coupled to a select gate line SGD1. Gates of the plurality of selection transistors ST1 in the string unit SU2 are commonly coupled to a select gate line SGD2. Gates of the plurality of selection transistors ST1 in the string unit SU3 are commonly coupled to a select gate line SGD3. Gates of the plurality of selection transistors ST1 in the string unit SU4 are commonly coupled to a select gate line SGD4. Gates of the plurality of selection transistors ST1 in the string unit SU5 are commonly coupled to a select gate line SGD5.

Gates of the selection transistors ST2 in the block BLK are commonly coupled to a select gate line SGS. Note that, similar to the select gate line SGD, the select gate line SGS may be provided for each string unit SU.

The word lines WL0 to WL7, the select gate lines SGD0 to SGD5, and the select gate line SGS are coupled to the row decoder 12.

The bit lines BL are commonly coupled to the NAND string NS in each string unit SU of each block BLK. Each bit line BL is coupled to the sense amplifier 13.

The source line SL is shared between, for example, the plurality of blocks BLK.

A set of the plurality of memory cell transistors MC coupled to the common word line WL in one string unit SU is written as, for example, a “cell unit CU”. In other words, the cell unit CU is a set of the plurality of memory cell transistors MC collectively selected in the write operation or the read operation. A page is a unit of data collectively written in (or collectively read from) the cell unit CU. If, for example, 1-bit data is stored in the memory cell transistor MC, the storage capacity of the cell unit CU is one page. Note that the cell unit CU can have a storage capacity equal to or more than two pages based on the number of bits of data stored in the memory cell transistor MC.

### 1.3 Planar Layout of Memory Cell Array

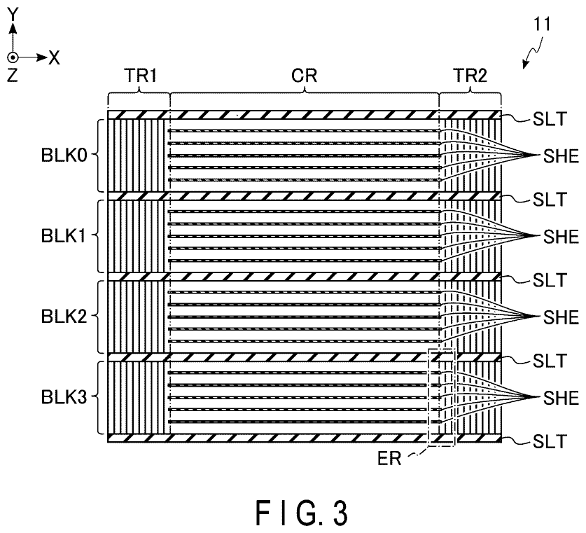

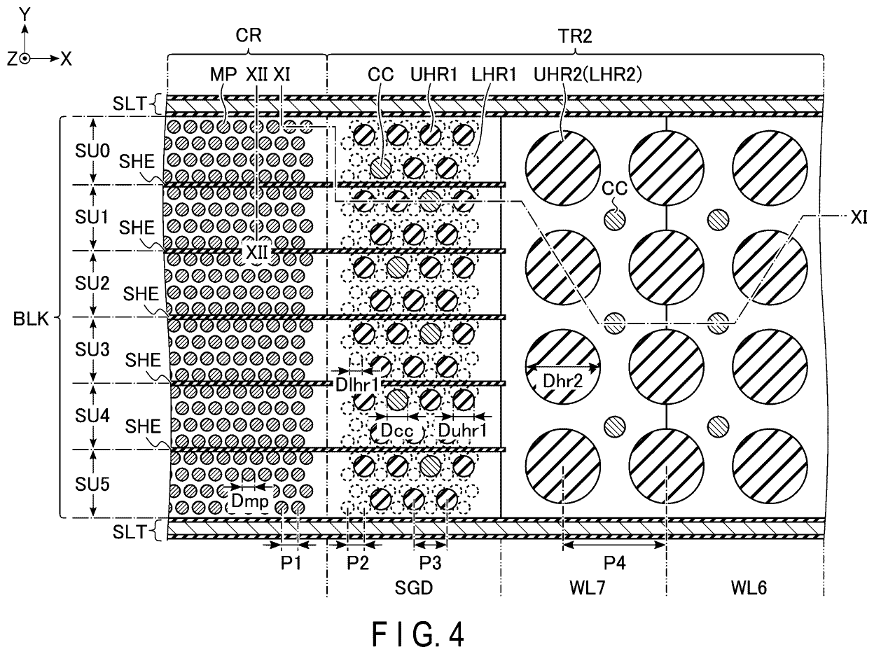

An example of a planar layout of the memory cell array 11 will be described next with reference to FIGS. 3 and 4. FIG. 3 is a plan view showing an example of a planar layout of the memory cell array 11. FIG. 4 is an enlarged view of the region ER in FIG. 3. The example shown in FIG. 3 indicates regions corresponding to the four blocks BLK0 to BLK3 included in the memory cell array 11. Note that part of interlayer insulating films in the example shown in FIGS. 3 and 4 is omitted. In order to facilitate the visualization of the plan views, hatching is added as needed. The hatching added to the plan views is not necessarily associated with the materials and characteristics of constituent elements to which the hatching is added. In order to facilitate the visualization of the cross-sectional views, the illustrations of configurations can be omitted as needed.

In the following description, a direction which is parallel to a substrate and in which the word line WL extends is defined as the X direction. A direction which is parallel to the substrate and intersects the X direction is defined as the Y direction. A direction which intersects the X direction and the Y direction and is vertical to the substrate is defined as the Z direction.

As shown in FIG. 3, the memory cell array 11 includes a terrace region TR1, a cell region CR, and a terrace region TR2. If the terrace regions TR1 and the terrace region TR2 are not distinguished from each other, each region is written as a “terrace region TR”.

The cell region CR is a region where the memory cell transistors MC are arranged.

The terrace region TR is a coupling region where the word lines WL and the select gate lines SGD and SGS are respectively coupled to corresponding contact plugs. The terrace regions TR1 and TR2 are provided on both sides of the cell region CR in the X direction. Note that the terrace region TR may be provided in the cell region CR. In the terrace region TR, both ends of each of the word lines WL and the select gate lines SGD and SGS which extend in the X direction are drawn in a stepped pattern. The portions of the word line WL, the select gate line SGD, and the select gate line SGS which are drawn in the stepped pattern will be written as “terraces” hereinafter. In the following description, if the region of the terrace region TR in which a terrace of the select gate line SGD is provided is to be distinguished, the region will be written as the “terrace region TR of the select gate line SGD”. The same applies to the other word lines WL0 to WL7 and the select gate line SGS. Note that in the terrace region TR, the word lines WL and the select gate lines SGD and SGS need not be drawn in the stepped pattern. In this case as well, it is possible to form contact plugs that are electrically coupled to a target interconnect layer but not electrically coupled to other interconnect layers.

In addition, the memory cell array 11 includes, for example, a plurality of members SLT and a plurality of members SHE.

Each member SLT extends in the X direction and crosses the terrace region TR1, the cell region CR, and the terrace region TR2. The plurality of members SLT are arranged in the Y direction. The member SLT has, for example, a structure in which an insulator is embedded. Note that the member SLT may include a conductor coupled to the source line SL. The members SLT divide the interconnect layers (for example, the word lines WL0 to WL7 and the select gate lines SGD and SGS) adjacent to each other through the member SLT. Each of the regions delimited by the members SLT corresponds to one block BLK.

Each member SHE extends in the X direction and crosses the cell region CR. The plurality of members SHE are arranged in the Y direction. In this embodiment, the five members SHE are arranged between the two members SLT adjacent to each other in the Y direction. Each member SHE has, for example, a structure in which an insulator is embedded. Each member SHE divides the interconnect layers (the select gate lines SGD) adjacent to each other through the member SHE. In the memory cell array 11, each of the regions delimited by the members SLT and SHE corresponds to one string unit SU.

Note that the number of members SHE arranged between the two adjacent members SLT can be designed to be an arbitrary number. The number of members SHE arranged between the two adjacent members SLT is based on the number of string units SU of each block BLK.

A planar configuration of the region ER will be described next in detail.

For example, in each block BLK, the select gate line SGS, the word lines WL0 to WL7, and the select gate line SGD are sequentially stacked from the substrate side and separated from each other in the Z direction. The select gate line SGS, the word lines WL0 to WL7, and the select gate line SGD extend in the X direction and have end portions (terraces) drawn in a stepped pattern.

As shown in FIG. 4, in the terrace region TR2, terraces respectively corresponding to the select gate line SGD, the word line WL7, and the word line WL6 are provided from the left side to the right side of the drawing surface. The same applies to the word lines WL0 to WL5 and the select gate line SGS (not shown). For example, in the terrace region TR2, terraces are sequentially provided from the cell region CR to the end portion in the X direction in the order of the select gate line SGD, the word lines WL7 to WL0, and the select gate line SGS. Two side surfaces of one block BLK which face in the Y direction are respectively provided with the members SLT. The members SLT extend in the X direction and the Z direction. The members SLT divide the select gate line SGS, the word lines WL0 to WL7, and the select gate line SGD stacked apart from each other for each block BLK. In the block BLK, the select gate line SGD is divided in the Y direction by the members SHE. The members SHE extend in the X direction. In the example shown in FIG. 4, the select gate line SGD is divided into six parts by the five members SHE. Each of the regions delimited by the members SLT and the members SHE corresponds to one string unit SU. In the example shown in FIG. 4, the six delimited regions sequentially correspond to the string units SU0 to SU5 from the upper side of the drawing surface. In other words, the select gate lines SGD0 to SGD5 are sequentially arranged from the upper side of the drawing surface in the Y direction.

The cell region CR is provided with a plurality of memory pillars MP. Each memory pillar MP is a pillar corresponding to the NAND string NS. The structure of the memory pillar MP will be described in detail later. The memory pillar MP extends in the Z direction. The memory pillar MP extends (passes) through the select gate line SGS, the word lines WL0 to WL7, and the select gate line SGD stacked in the Z direction.

In the example shown in FIG. 4, the plurality of memory pillars MP of the cell region CR are staggered in the X direction. Note that the arrangement of the memory pillars MP can be arbitrarily designed. For example, the arrangement of the memory pillars MP may not be a staggered arrangement. The diameter (size) of the upper surface of the memory pillar MP will be written as a “diameter Dmp” hereinafter. Note that the upper surface (the shape of the opening portion) of the memory pillar MP may not be a true circle. A pitch of the two adjacent memory pillars MP (a distance between a central axes of the two pillars which extend in the Z direction) is written as a “pitch P1”.

The terrace regions TR1 and TR2 include a plurality of contact plugs CC and a plurality of support pillars HR.

One end of each of the contact plugs CC is coupled to the terrace of an interconnect layer corresponding to any one of the select gate line SGS, the word lines WL0 to WL7, and the select gate line SGD. The contact plug CC is not electrically coupled to other interconnect layers. For example, the contact plug CC coupled to the terrace of the select gate line SGD is not electrically coupled to the select gate line SGS and the word lines WL0 to WL7. The other end of the contact plug CC is electrically coupled to the row decoder 12. The example shown in FIG. 4 is provided with the five contact plugs CC respectively coupled to the select gate lines SGD0 to SGD5, the three contact plugs CC coupled to the word line WL7, and the three contact plugs CC coupled to the word line WL6. Note that the number of contact plugs CC coupled to each interconnect layer may be one or more. In this embodiment, a diameter (size) of an upper surface of the contact plug CC coupled to any of the select gate lines SGD is almost equal to a diameter (size) of an upper surface of the contact plug CC coupled to any of the word lines WL0 to WL7 and the select gate line SGS. Note that if the diameters are set to be almost equal to each other, these settings can include variations originating from manufacturing processes. The diameter of the upper surface of the contact plug CC in this embodiment will be written as a “diameter Dcc” hereinafter. Note that the upper surface (the shape of the opening portion) of the contact plug CC may not be a true circle. For example, the diameter Dcc of the contact plug CC is larger than the diameter Dmp of the memory pillar MP.

Methods of forming the word lines WL and the select gate lines SGD and SGS include, for example, a method (to be referred to as “replace” hereinafter) of forming a structure equivalent to each interconnect layer by using a sacrificial film and then forming an interconnect layer by replacing the sacrificial film with a conductive material. In “replace”, after an air gap is formed by removing the sacrificial film, the air gap is filled with the conductive material.

The support pillar HR functions as a pillar that supports interlayer insulating films each having an air gap in the replace. For example, the support pillar HR has a substantially columnar structure filled with an insulator. The support pillar HR is not electrically coupled to the source line SL, the word lines WL, and the select gate lines SGD and SGS. The support pillar HR extends in the Z direction. In the terrace region TR, the support pillar HR extends (passes) through the select gate line SGS, the word lines WL0 to WL7, and the select gate line SGD stacked in the Z direction. Note that the arrangement of the support pillar HR is arbitrary.

Each support pillar HR includes a lower support pillar LHR and an upper support pillar UHR provided on the lower support pillar LHR. Note that the support pillar HR may include three or more pillars. That is, the support pillar HR may have a structure having three or more pillars stacked on each other. If the lower support pillar LHR and the upper support pillar UHR provided in the terrace region TR of the select gate line SGD are to be distinguished, they are respectively written as a “lower support pillar LHR1” and an “upper support pillar UHR1”. If the lower support pillar LHR and the upper support pillar UHR provided for the terrace region TR of the word line WL (and the select gate line SGS (not shown)) are to be distinguished, they are respectively written as a “lower support pillar LHR2” and an “upper support pillar UHR2”.

As shown in FIG. 4, in the terrace region TR of the select gate line SGD, the lower support pillars LHR1 and the upper support pillars UHR1 are respectively arranged in staggered patterns. Diameter and layout of upper surfaces of the lower support pillars LHR1 differ from diameter and layout of the upper support pillars UHR1. The diameter of the upper surface of the lower support pillar LHR1 is written as a “diameter Dlhr1”, and the diameter of the upper surface of the upper support pillar UHR1 is written as a “diameter Duhr1”. Note that the upper surfaces (the shapes of the opening portions) of the lower support pillar LHR1 and the upper support pillar UHR1 may not be true circles. For example, the diameter Dlhr1 of the lower support pillar LHR1 is almost equal to the diameter Dmp of the memory pillar MP. The diameter Duhr1 of the upper support pillar UHR1 is larger than the diameter Dlhr1 of the lower support pillar LHR1. That is, the diameter Duhr1 of the upper support pillar UHR1 is larger than the diameter Dmp of the memory pillar MP. For example, the diameter Dcc of the contact plug CC is equal to or larger than the diameter Duhr1 of the upper support pillar UHR1.

A pitch of the two adjacent lower support pillars LHR1 is written as a “pitch P2”, and a pitch of the two adjacent upper support pillars UHR1 is written as a “pitch P3”. For example, the pitch P2 of the lower support pillars LHR1 is almost equal to the pitch P1 of the memory pillars MP. The pitch P3 of the upper support pillars UHR1 is larger than the pitch P2 of the lower support pillars LHR1. For example, the pitch P3 of the upper support pillars UHR1 is set to be twice the pitch P2 of the lower support pillars LHR1. The upper support pillar UHR1 is preferably arranged at the center of the three lower support pillars LHR1 arranged in a triangle form in plan view in the Z direction.

In the terrace region TR of each select gate line SGD, the contact plug CC is arranged, for example, at the layout position of the upper support pillar UHR1 so as to replace it.

In the terrace region TR of the word lines WL and the select gate line SGS, the lower support pillars LHR2 and the upper support pillars UHR2 are respectively arranged in matrix patterns. A diameter and layout of the upper surfaces of the lower support pillars LHR2 are equal to a diameter and layout of the upper surfaces of the upper support pillars UHR2. The upper support pillar UHR2 is provided on the lower support pillar LHR2. The diameter of the upper surfaces of the lower support pillar LHR2 and the upper support pillar UHR2 is written as a “diameter Dhr2”. Note that the upper surfaces (the shapes of the opening portions) of the lower support pillar LHR2 and the upper support pillar UHR2 may not be true circles. The diameter Dhr2 of the lower support pillar LHR2 and the upper support pillar UHR2 is larger than the diameter Duhr1 of the upper support pillar UHR1. Accordingly, in this embodiment, the diameter Dmp, the diameter Dlhr1, the diameter Duhr1, and the diameter Dhr2 have a relationship of Dmp=Dlhr1<Duhr1<Dhr2.

A pitch of the two adjacent lower support pillars LHR2 or the two adjacent upper support pillars UHR2 is written as a “pitch P4”. The pitch P4 is larger than the pitch P3 of the upper support pillars UHR1. Accordingly, in this embodiment, the pitches P1 to P4 have a relationship of P1=P2<P3<P4.

In the terrace region TR of the word lines WL (and the select gate line SGS (not shown)), the contact plug CC is placed at, for example, a center of the four upper support pillars UHR2 arranged in a rectangle form in top view in the Z direction.

### 1.4 Cross-Sectional Configuration of Memory Cell Array

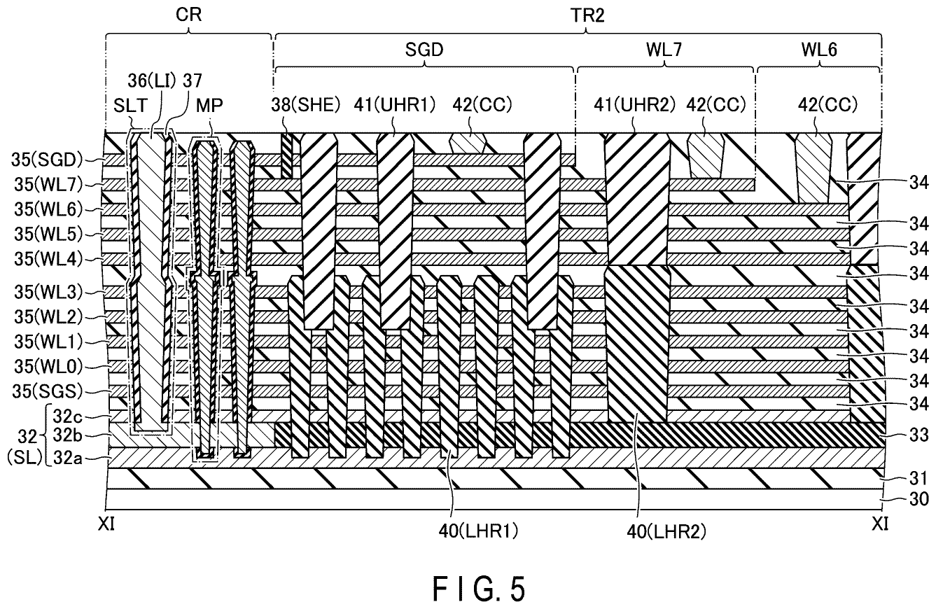

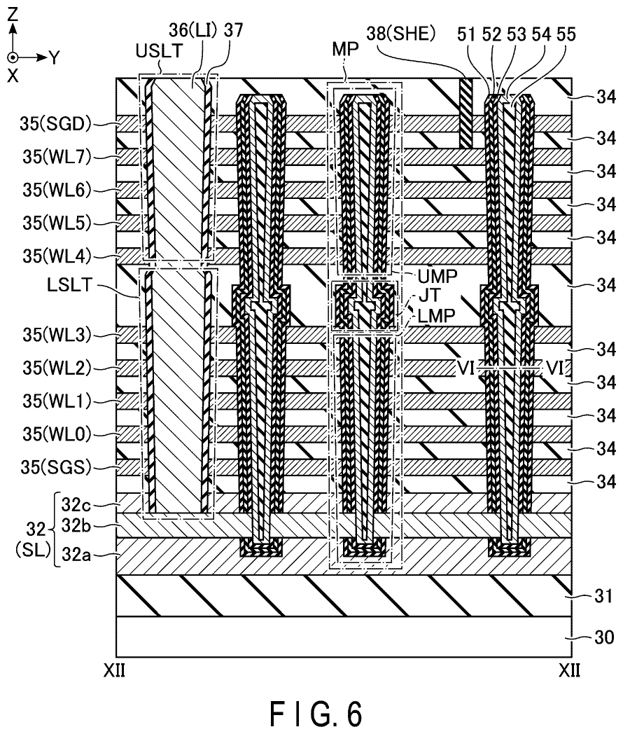

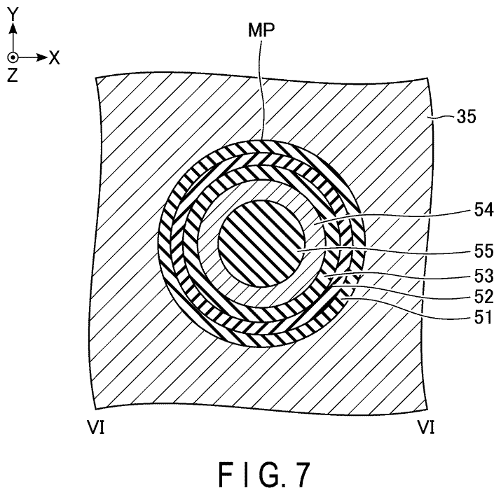

An example of a cross-sectional configuration of the memory cell array 11 will be described next with reference to FIGS. 5, 6, and 7. FIG. 5 is a cross-sectional view of the memory cell array 11 taken along line XI-XI in FIG. 4. FIG. 6 is a cross-sectional view of the memory cell array 11 taken along line XII-XII in FIG. 4. FIG. 7 is a cross-sectional view of the memory pillar MP in an XY plane taken along line VI-VI in FIG. 6. In the example shown in FIG. 5, to simplify explanation, the illustrations of conductors (contact plugs, interconnect layers, bit lines BL, or the like) provided on the memory pillars MP, the contact plugs CC, and the member SLT are omitted.

As shown in FIG. 5, the memory cell array 11 includes a semiconductor layer 32, insulating layers 33 and 34, interconnect layers 35, conductors 36 and 42, and insulators 37, 38, 40, and 41, and the memory pillars MP.

An insulating layer 31 is provided on a semiconductor substrate 30. For example, the insulating layer 31 contains silicon oxide. Note that the region where the insulating layer 31 is provided, that is, the region between the semiconductor substrate 30 and the semiconductor layer 32, may be provided with circuits such as the row decoder 12 and the sense amplifier 13.

The semiconductor layer 32 functioning as the source line SL is provided on the insulating layer 31. The semiconductor layer 32 extends in the X direction and the Y direction. The semiconductor layer 32 includes three semiconductor layers 32a, 32b, and 32c. The semiconductor layer 32a is provided on the insulating layer 31. The semiconductor layer 32b is provided on the semiconductor layer 32a. The semiconductor layer 32c provided on the semiconductor layer 32b. In the example shown in FIG. 5, the semiconductor layer 32b is provided in the cell region CR but is not provided in the terrace region TR. Note that the semiconductor layer 32b may be also provided in the terrace region TR. The semiconductor layer 32b is formed by replacing the insulating layer 33 provided between the semiconductor layer 32a and the semiconductor layer 32c. The semiconductor layers 32a to 32c contain, for example, silicon. In addition, the semiconductor layers 32a to 32c contain, for example, phosphorus (P) as an n-type semiconductor impurity.

The insulating layer 34 is provided on the semiconductor layer 32. The insulating layer 34 contains, for example, silicon oxide.

In the insulating layer 34, for example, the 10 interconnect layers 35 are stacked apart from each other in the Z direction above the semiconductor layer 32. In other words, the plurality of insulating layers 34 and the plurality of interconnect layers 35 are alternately stacked one by one. For example, the 10 interconnect layers 35 function as the select gate line SGS, the word lines WL0 to WL7, and the select gate line SGD in the order from the lower layer. Note that a plurality of interconnect layers 35 functioning as the selection gates SGS or SGD may be provided. For example, as a conductive material for the interconnect layer 35, a stacked layer structure made of titanium nitride (TiN)/tungsten (W) is used. In this case, titanium nitride is formed to cover tungsten. Titanium nitride functions as a barrier layer for suppressing the oxidation of tungsten or an adhesive layer for improving the adhesion of tungsten at the time of forming a tungsten film by chemical vapor deposition (CVD). The interconnect layer 35 can contain a high dielectric constant material such as aluminum oxide (AlO). In this case, the high dielectric constant material is formed to cover the conductive material. For example, the high dielectric constant material is provided to be in contact with the insulating layers 34 provided on and under each of the interconnect layers 35 and a side surface of the memory pillar MP. Titanium nitride is provided to be in contact with the high dielectric constant material. In addition, tungsten is provided to fill the inside of the interconnect layer 35 so as to be in contact with the titanium nitride. If, for example, aluminum oxide is provided as a high dielectric constant material, the memory cell transistor MC is written as a metal-aluminum-nitride-oxide-silicon (MANOS) type transistor.

A internal configuration of the member SLT will be described next.

As shown in FIGS. 5 and 6, each member SLT includes a lower member LSLT and an upper member USLT provided on the lower member LSLT. That is, the member SLT is processed in two steps. Note that the member SLT may be processed in one step or may be processed in three or more steps. The member SLT extends in the X direction and the Z direction. The member SLT extends (passes) through the 10 interconnect layers 35 and 11 insulating layers 34. More specifically, for example, the lower member LSLT passes through the five interconnect layers 35 functioning as the select gate line SGS and the word lines WL0 to WL3. For example, the upper member USLT passes through the five interconnect layers 35 functioning as the word lines WL4 to WL7 and the select gate line SGD. The lower end of the member SLT (the lower end of the lower member LSLT) reaches the semiconductor layer 32b. In the following description, the plurality of interconnect layers 35 respectively corresponding to the select gate line SGS and the word lines WL0 to WL3 will also be referred to as a “lower tier”. The plurality of interconnect layers 35 respectively corresponding to the word lines WL4 to WL7 and the select gate line SGD will also be referred to as an “upper tier”.

The member SLT includes the conductor 36 and the insulator 37. The conductor 36 and the insulator 37 are respectively formed as continuous films in, for example, the lower member LSLT and the upper member USLT.

The conductor 36 extends in the X direction and the Z direction. The conductor 36 functions as a contact plug LI. A side surface of the conductor 36 is in contact with the insulator 37. The bottom surface of the conductor 36 is in contact with the semiconductor layer 32.

The insulator 37 is provided so as to surround a side surface of the conductor 36. The insulator 37 prevents the conductor 36 from being electrically coupled to the interconnect layer 35. For example, the insulator 37 contains silicon oxide.

A internal configuration of the memory pillar MP will be described next.

As shown in FIG. 6, the memory pillar MP includes a lower memory pillar LMP, a joint portion JT, and an upper memory pillar UMP. For example, the lower memory pillar LMP passes through the five interconnect layers 35 functioning as the select gate line SGS and the word lines WL0 to WL3, that is, the lower tier. For example, the upper memory pillar UMP passes through the five interconnect layers 35 functioning as the word lines WL4 to WL7 and the select gate line SGD, that is, the upper tier. The joint portion JT is formed on the lower memory pillar LMP and electrically couples between the lower memory pillar LMP and the upper memory pillar UMP. That is, the memory pillar MP is processed in two steps. Note that the memory pillar MP may be processed in one step or may be processed in three or more steps.

The memory pillar MP is provided so as to extend in the Z direction and passes through the 10 interconnect layers 35 and the 10 insulating layers 34. The bottom portion of the memory pillar MP reaches the semiconductor layer 32a. The lower memory pillar LMP and the upper memory pillar UMP each have, for example, a tapered shape. The diameter of the joint portion JT along an XY plane is larger than, for example, the diameters of the lower memory pillar LMP and the upper memory pillar UMP at the portion in contact with the joint portion JT.

The memory pillar MP includes a block insulating film 51, a charge storage film 52, a tunnel insulating film 53, a semiconductor film 54, and a core film 55. The block insulating film 51, the charge storage film 52, the tunnel insulating film 53, the semiconductor film 54, and the core film 55 are respectively formed as continuous films in, for example, the lower memory pillar LMP, the joint portion JT, and the upper memory pillar UMP.

The block insulating film 51, the charge storage film 52, and the tunnel insulating film 53 are sequentially stacked from outside on part of a side surface of the memory pillar MP and the bottom surface in contact with the semiconductor layer 32. More specifically, the block insulating film 51, the charge storage film 52, and the tunnel insulating film 53 provided on a side surface of the memory pillar MP are removed from the same layer as the semiconductor layer 32b and its neighborhood. The semiconductor film 54 is provided so as to be in contact with a side surface and the bottom surface of the tunnel insulating film 53 and the semiconductor layer 32b. The semiconductor film 54 is a region where the channels of the memory cell transistors MC and the selection transistors ST1 and ST2 are formed. The semiconductor film 54 extends in the Z direction. An inside of the semiconductor film 54 is filled with the core film 55.

For example, the block insulating film 51, the tunnel insulating film 53, and the core film 55 contain silicon oxide. For example, the charge storage film 52 contains silicon nitride (SiN). For example, the semiconductor film 54 contains silicon.

A cross-sectional structure of the memory pillar MP taken along an XY plane will be described.

As shown in FIG. 7, in a cross-section including the interconnect layer 35, the core film 55 is provided at a central portion of the memory pillar MP. The semiconductor film 54 surrounds a side surface of the core film 55. The tunnel insulating film 53 surrounds the side surface of the semiconductor film 54. The charge storage film 52 surrounds a side surface of the tunnel insulating film 53. The block insulating film 51 surrounds a side surface of the charge storage film 52. The interconnect layer 35 surrounds a side surface of the block insulating film 51.

As shown in FIG. 6, the semiconductor film 54 is used as a channel (current path) for the memory cell transistors MC0 to MC7 and the selection transistors ST1 and ST2. A portion where the memory pillar MP intersects the interconnect layer 35 functioning as the select gate line SGS functions as the selection transistor ST2. Portions where the memory pillar MP intersects the eight interconnect layers 35 functioning as the word lines WL0 to WL7 respectively function as the memory cell transistors MC0 to MC7. A portion where the memory pillar MP intersects the interconnect layer 35 functioning as the select gate line SGD functions as the selection transistor ST1.

The member SHE will be described next.

The member SHE separates the interconnect layers 35 functioning as the select gate lines SGD. In other words, the member SHE separates at least the interconnect layer 35 which is provided at a position farthest from the semiconductor layer 32 among the plurality of interconnect layers 35. The upper end of the member SHE is positioned above the uppermost interconnect layer 35. The lower end of the member SHE is positioned at the layer between the interconnect layer 35 functioning as the select gate line SGD and the interconnect layer 35 functioning as the word line WL. The total number of interconnect layers 35 divided by the member SHE increases in accordance with the number of interconnect layers 35 functioning as the select gate lines SGD. For example, the member SHE is filled with the insulator 38. The insulator 38 contains, for example, silicon oxide. The upper end of the member SHE and the upper end of the member SLT may or may not be aligned. In addition, the upper ends of the member SHE and the upper end of the memory pillar MP may or may not be aligned.

The support pillar HR will be described next.

As shown in FIG. 5, in the terrace region TR of the select gate line SGD, the lower support pillar LHR1 is provided so as to extend in the Z direction. The lower support pillar LHR1 has, for example, a tapered shape. The lower support pillar LHR1 passes through, for example, the five interconnect layers 35 respectively functioning as the select gate line SGS and the word lines WL0 to WL3, that is, the lower tier. The lower end (bottom portion) of the lower support pillar LHR1 reaches the semiconductor layer 32a. The upper end of the lower support pillar LHR1 is positioned between, for example, the interconnect layer 35 functioning as the word line WL3 and the interconnect layer 35 functioning as the word line WL4. The lower support pillar LHR1 is filled with the insulator 40. The insulator 40 contains, for example, silicon oxide.

In the terrace region TR of the select gate line SGD, the upper support pillar UHR1 is provided so as to extend in the Z direction. The upper support pillar UHR1 has, for example, a tapered shape. For example, the upper support pillar UHR1 is provided at a position different from that of the lower support pillar LHR1 in an XY plane. In other words, a position of a central axis of the upper support pillar UHR1 which extends in the Z direction is different, in the X direction and the Y direction, from a position of a central axis of the lower support pillar LHR1 which extends in the Z direction. The upper support pillar UHR1 passes through the seven interconnect layers 35 respectively functioning as the word lines WL2 to WL7 and the select gate line SGD and the insulating layers 34. That is, the upper support pillar UHR1 passes through the interconnect layers 35 of the upper tier and some interconnect layers 35 of the lower tier. For example, a lower end of the upper support pillar UHR1 is positioned between the interconnect layer 35 functioning as the word line WL2 and the interconnect layer 35 functioning as the word line WL1. The lower end of the upper support pillar UHR1 is positioned on the lower side (the side near the semiconductor layer 32) of the one or more interconnect layers 35 relative to the upper end of the lower support pillar LHR1. The upper support pillar UHR1 is in contact with the lower support pillar LHR1 and extends (passes) through a portion of the lower support pillar LHR1 which is located near the upper end and at least one of the interconnect layers 35 of the lower tier. An upper end of the upper support pillar UHR1 is positioned above the uppermost interconnect layer 35 functioning as the select gate line SGD. The upper support pillar UHR1 is filled with the insulator 41. The insulator 41 contains, for example, silicon oxide. Note that the insulator 40 and the insulator 41 may be made of the same material.

In the terrace region TR of the word lines WL and the select gate line SGS, the lower support pillars LHR2 are provided so as to extend in the Z direction. The lower support pillar LHR2 has, for example, a tapered shape. The lower support pillar LHR2 passes through the lower tier. More specifically, the lower support pillar LHR2 provided in the terrace region TR of the select gate line SGS passes through the interconnect layer 35 functioning as the select gate line SGS. The lower support pillar LHR2 provided in the terrace region TR of the word line WL0 passes through the two interconnect layers 35 respectively functioning as the select gate line SGS and the word line WL0. The lower support pillar LHR2 provided in the terrace region TR of the word line WL1 passes through the three interconnect layers 35 respectively functioning as the select gate line SGS and the word lines WL0 and WL1. The lower support pillar LHR2 provided in the terrace region TR of the word line WL2 passes through the four interconnect layers 35 respectively functioning as the select gate line SGS and the word lines WL0 to WL2. The lower support pillars LHR2 provided in the terrace region TR of the word lines WL3 to WL7 pass through the five interconnect layers 35 respectively functioning as the select gate line SGS and the word lines WL0 to WL3. A lower end of each lower support pillar LHR2 reaches the semiconductor layer 32. In the example shown in FIG. 5, although the lower end of the lower support pillar LHR2 is in contact with the insulating layer 33 positioned between the semiconductor layer 32a and the semiconductor layer 32c, this is not exhaustive. For example, the lower end of the lower support pillar LHR2 may reach the semiconductor layer 32a. Similar to the lower support pillar LHR1, an upper end of the lower support pillar LHR2 is positioned between, for example, the interconnect layer 35 functioning as the word line WL3 and the interconnect layer 35 functioning as the word line WL4. Similar to the lower support pillar LHR1, the lower support pillar LHR2 is filled with the insulator 40.

In the terrace region TR of the word lines WL and the select gate line SGS, the upper support pillars UHR2 are provided so as to extend in the Z direction. The upper support pillar UHR2 has, for example, a tapered shape. The upper support pillar UHR2 passes through the upper tier. More specifically, the upper support pillar UHR2 provided in the terrace region TR of the select gate line SGS and the word lines WL0 to WL3 does not pass through any of the interconnect layers 35. The upper support pillar UHR2 provided in the terrace region TR of the word line WL4 passes through the interconnect layer 35 functioning as the word line WL4. The upper support pillar UHR2 provided in the terrace region TR of the word line WL5 passes through the two interconnect layers 35 respectively functioning as the word lines WL4 and WL5. The upper support pillar UHR2 provided in the terrace region TR of the word line WL6 passes through the three interconnect layers 35 respectively functioning as the word lines WL4 to WL6. The upper support pillar UHR2 provided in the terrace region TR of the word line WL7 passes through the four interconnect layers 35 respectively functioning as the word lines WL4 to WL7. A lower end of each upper support pillar UHR2 is in contact with the upper end of the lower support pillar LHR2. The upper support pillar UHR2 hardly extends through the lower support pillar LHR2. The upper support pillar UHR2 does not pass through the interconnect layer 35. Similar to the upper support pillar UHR1, an upper end of the upper support pillar UHR2 is positioned above the uppermost interconnect layer 35 functioning as the select gate line SGD. Similar to the upper support pillar UHR1, the upper support pillar UHR2 is filled with the insulator 41.

In the terrace region TR, the contact plug CC is provided on each terrace. The contact plug CC is provided so as to extend in the Z direction. The contact plug CC has, for example, a tapered shape. A lower end of the contact plug CC is in contact with the corresponding interconnect layer 35. An upper end of the contact plug CC is positioned above the uppermost interconnect layer 35 functioning as the select gate line SGD. The heights of the contact plugs CC differ depending on the positions (heights) of the terraces to which they are coupled. The contact plug CC is filled with the conductor 42. The conductor 42 contains, for example, tungsten or copper.

### 1.5 Method of Manufacturing Memory Cell Array

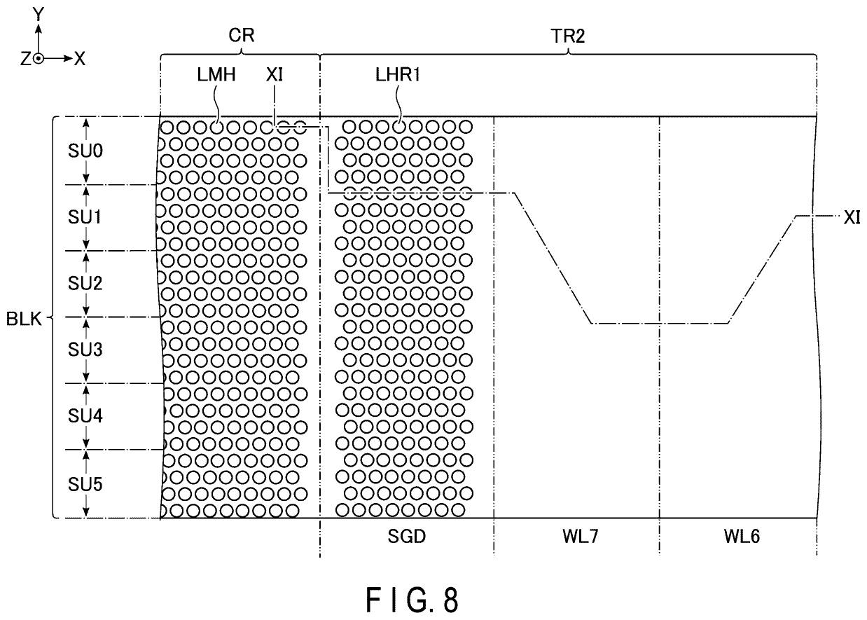

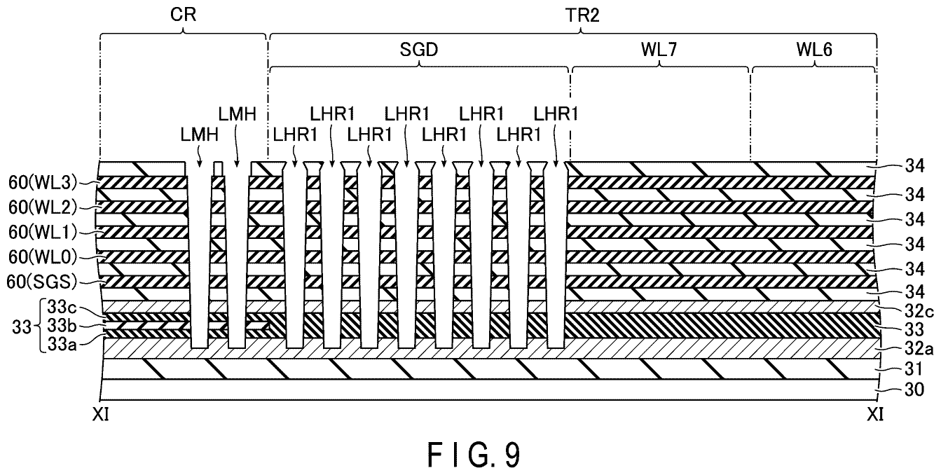

An example of a method of manufacturing the memory cell array 11 will be described next with reference to FIGS. 8 to 35. FIGS. 8, 10, 12, 14, 16, 18, 20, 22, 24, 26, 28, 30, 32, and 34 are plan views of the memory cell array 11 showing a manufacturing process for the memory cell array 11. FIGS. 9, 11, 13, 15, 17, 19, 21, 23, 25, 27, 29, 31, 33, and 35 are cross-sectional views of the memory cell array 11 showing a manufacturing process for the memory cell array 11. In the following description, focus is placed on a manufacturing process for the support pillar HR. The following is a description of a case where a slit corresponding to the member SLT, a hole (to be also referred to as a “memory hole”) corresponding to the memory pillar MP, and a hole corresponding to the support pillar HR each are formed in two steps. Note that the member SLT, the memory pillar MP, and the support pillar HR each may be formed by one etching process or by three or more etching processes.

As shown in FIGS. 8 and 9, first of all, the insulating layer 31 is formed on the semiconductor substrate 30. The semiconductor layer 32a is formed on the insulating layer 31. The insulating layer 33 is formed on the semiconductor layer 32a. More specifically, the insulating layer 33 includes, for example, three insulating layers 33a, 33b, and 33c. For example, the insulating layers 33a and 33c contain silicon oxide. The insulating layer 33b contain silicon nitride. Note that the insulating layer 33b is formed in the cell region CR where the replace of the insulating layer 33 is executed but is not formed in the terrace region TR where the replace of the insulating layer 33 is not executed in a step described later. The semiconductor layer 32c is formed on the insulating layer 33. The six insulating layers 34 and five sacrificial films 60 are alternately stacked one by one on the semiconductor layer 32c. The five sacrificial films 60 correspond to the lower tier and are replaced with the five interconnect layers 35 respectively functioning as the select gate line SGS and the word lines WL0 to WL3 in the step described later. For example, silicon nitride is used for the sacrificial film 60.

In this state, a plurality of memory holes LMH corresponding to the lower memory pillars LMP and the joint portion JT and a plurality of holes corresponding to the lower support pillars LHR1 are formed. Lower ends of the memory hole LMH and the hole corresponding to the lower support pillar LHR1 reach the semiconductor layer 32a.

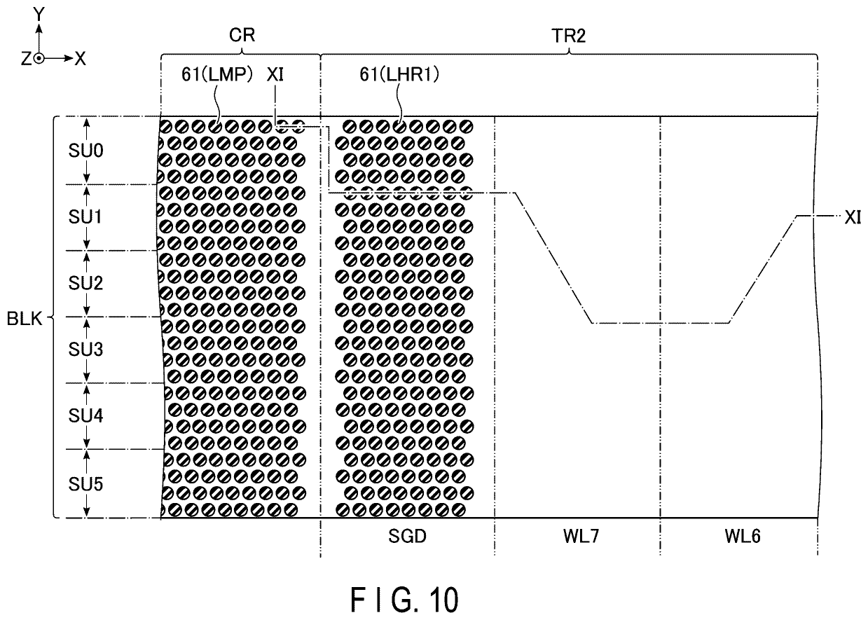

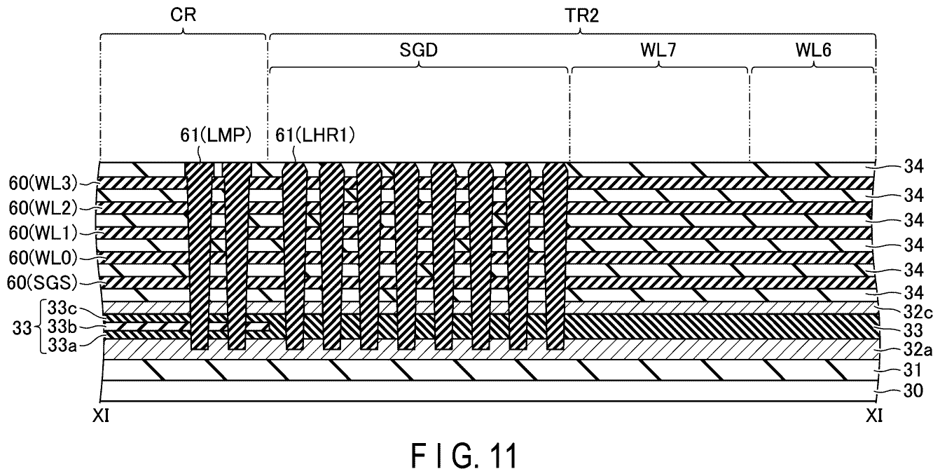

As shown in FIGS. 10 and 11, the memory holes LMH and the holes corresponding to the lower support pillars LHR1 are filled with a sacrificial film 61. The sacrificial film 61 may contain carbon, silicon, or a metal material such as tungsten or titanium nitride.

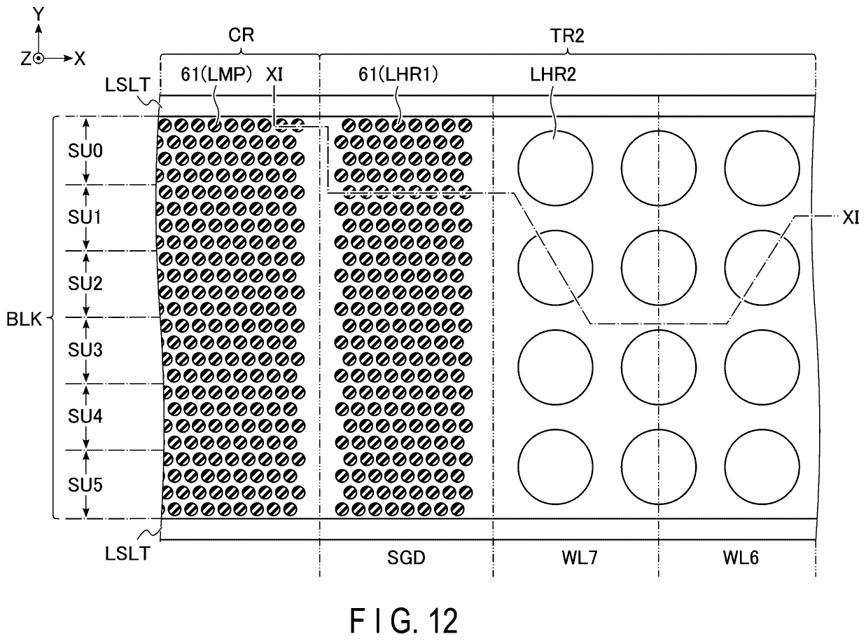

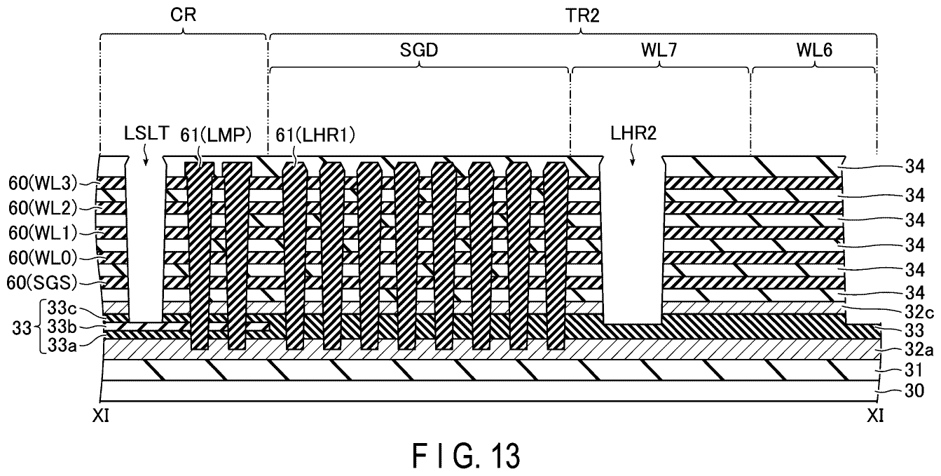

As shown in FIGS. 12 and 13, after the insulating layers 34 are formed to protect the upper surfaces of the sacrificial films 61, a plurality of slits corresponding to the lower members LSLT and a plurality of holes corresponding to the lower support pillars LHR2 are collectively processed. A lower ends of the slit corresponding to the lower member LSLT and the hole corresponding to the lower support pillar LHR2 reach the insulating layer 33.

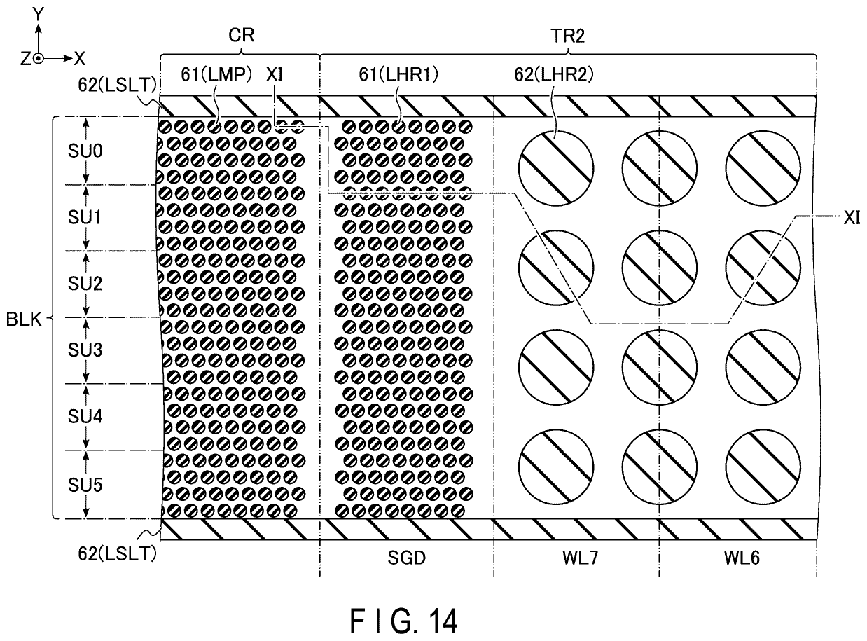

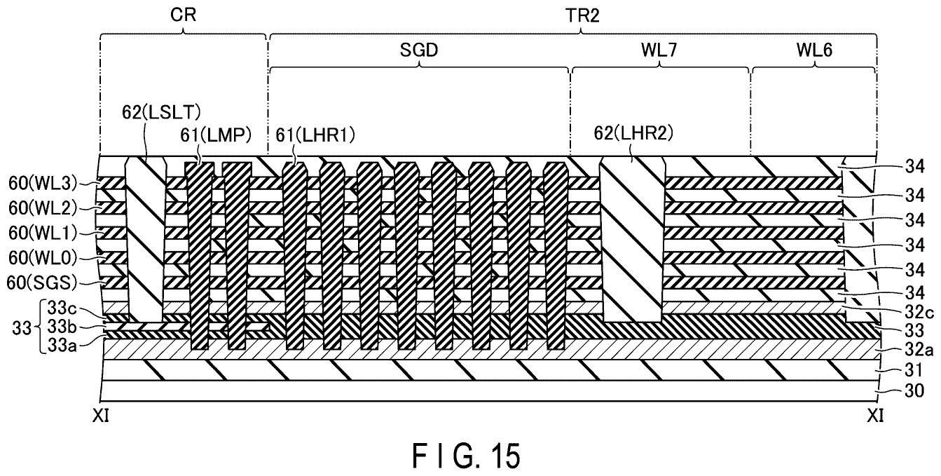

As shown in FIGS. 14 and 15, the slits corresponding to the lower members LSLT and the holes corresponding to the lower support pillars LHR2 are filled with sacrificial films 62. The sacrificial film 62 may contain carbon, silicon, or a metal material such as tungsten or titanium nitride.

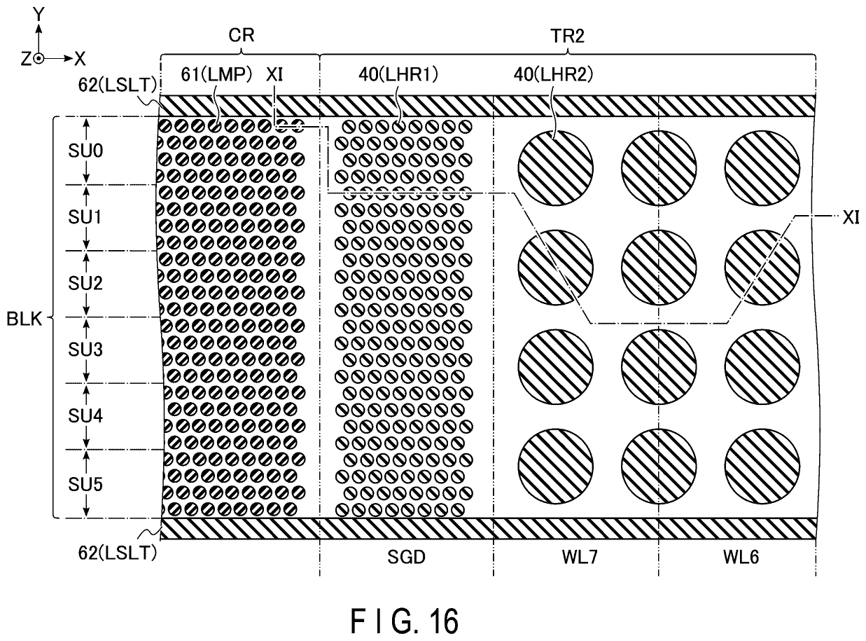

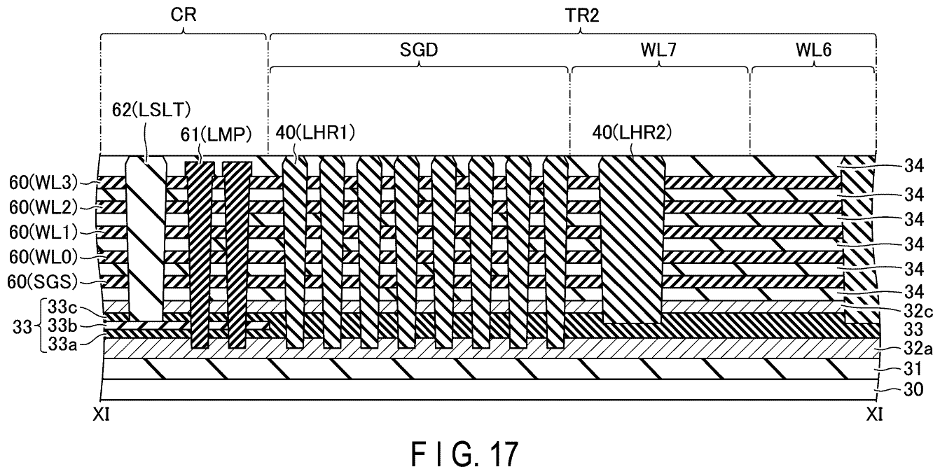

As shown in FIGS. 16 and 17, in the terrace region TR, the sacrificial film 61 in the hole corresponding to the lower support pillar LHR1 and the sacrificial film 62 in the hole corresponding to the lower support pillar LHR2 are removed, and each hole is filled with the insulator 40.

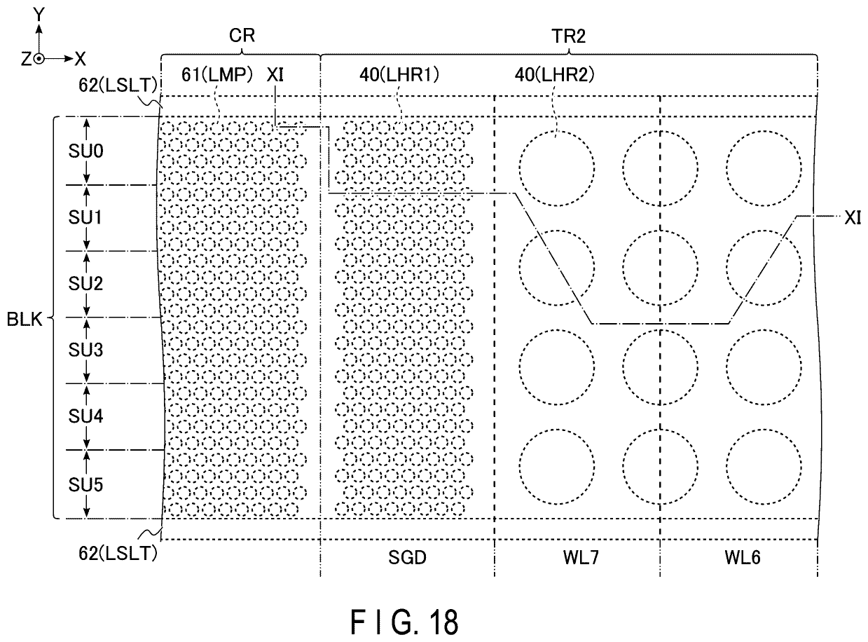

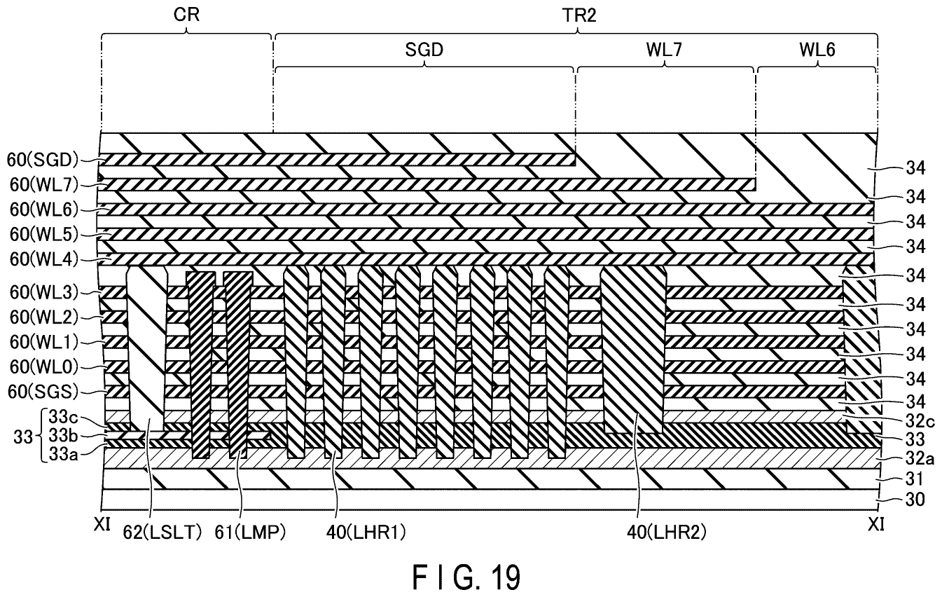

As shown in FIGS. 18 and 19, the five sacrificial films 60 and the five insulating layers 34 are alternately stacked one by one. The five sacrificial films 60 correspond to the upper tier and are replaced with the five interconnect layers 35 respectively functioning as the word lines WL4 to WL7 and the select gate line SGD. The sacrificial films 60 in the terrace region TR are processed in a stepped form to form regions corresponding to the terraces of the respective interconnect layers 35. Thereafter, the insulating layers 34 are formed to planarize the overall structure by chemical mechanical polishing (CMP).

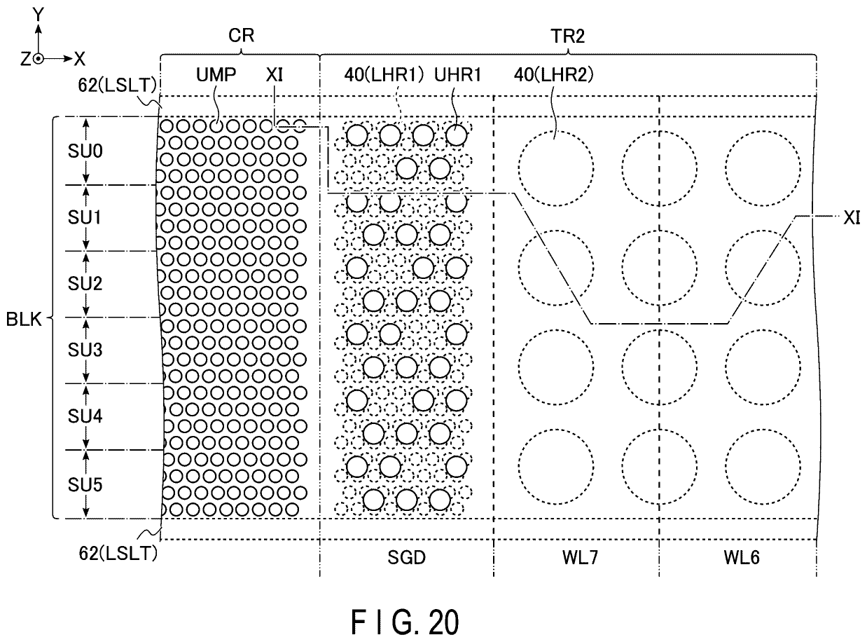

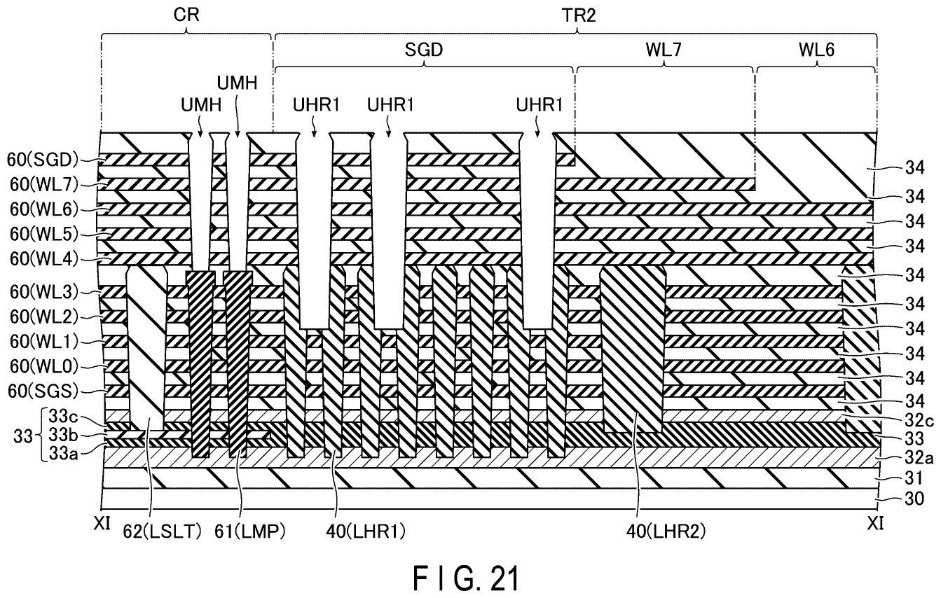

As shown in FIGS. 20 and 21, a plurality of memory holes UMH corresponding to the upper memory pillars UMP and a plurality of holes corresponding to the upper support pillars UHR1 are collectively formed. A lower end of the memory hole UMH reaches the sacrificial film 61 filling the memory hole LMH. The diameter Duhr1 of the upper support pillar UHR1 is larger than the diameter Dmp of the memory pillar MP. For this reason, if the memory hole UMH and the hole corresponding to the upper support pillar UHR1 are collectively processed, the depth of the hole corresponding to the upper support pillar UHR1 becomes deeper than the depth of the memory hole UMH. That is, a height position of the lower end of the hole corresponding to the upper support pillar UHR1 becomes lower than a height position of the lower end of the memory hole UMH (becomes near the semiconductor layer 32). For this reason, the hole corresponding to the upper support pillar UHR1 penetrates (passes) through part of the lower support pillar LHR1 which is located near an upper end and at least one of the plurality of sacrificial films 60 corresponding to the lower tier. In the example shown in FIG. 21, a lower end of the hole corresponding to the upper support pillar UHR1 reaches between the sacrificial film 60 corresponding to the word line WL1 and the sacrificial film 60 corresponding to the word line WL2.

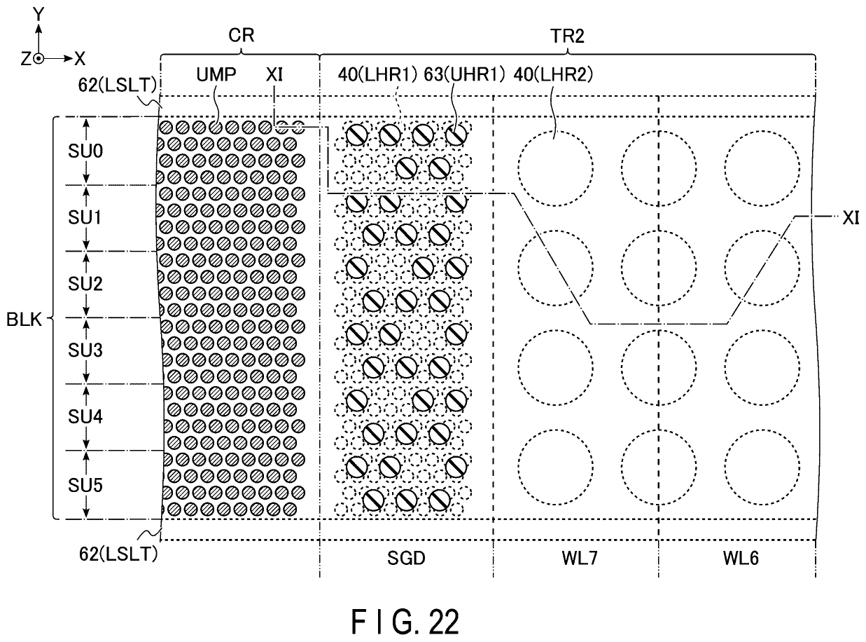

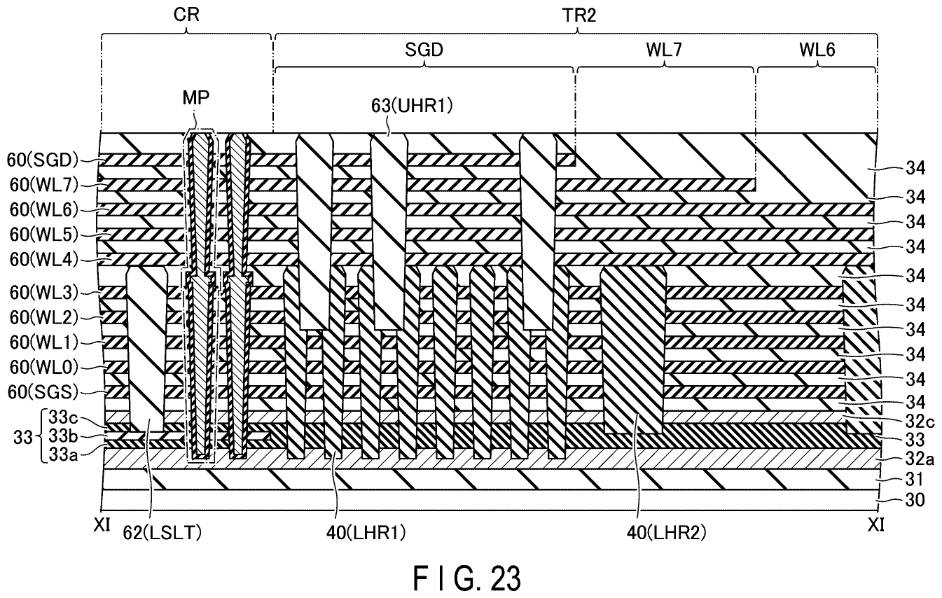

As shown in FIGS. 22 and 23, the holes corresponding to the upper support pillars UHR1 are filled with a sacrificial film 63. For example, the sacrificial film 63 contains silicon. More specifically, the memory holes UMH and the holes corresponding to the upper support pillars UHR1 are filled with the sacrificial films 63. The memory pillar MP is then formed. More specifically, the sacrificial film 61 in the memory hole LMH and the sacrificial film 63 in the memory hole UMH are removed. The block insulating film 51, the charge storage film 52, the tunnel insulating film 53, the semiconductor film 54, and the core film 55 are sequentially formed to fill the memory hole LMH and the memory hole UMH, and the block insulating film 51, the charge storage film 52, the tunnel insulating film 53, the semiconductor film 54, and the core film 55 on the insulating layer 34 are removed to form the memory pillar MP.

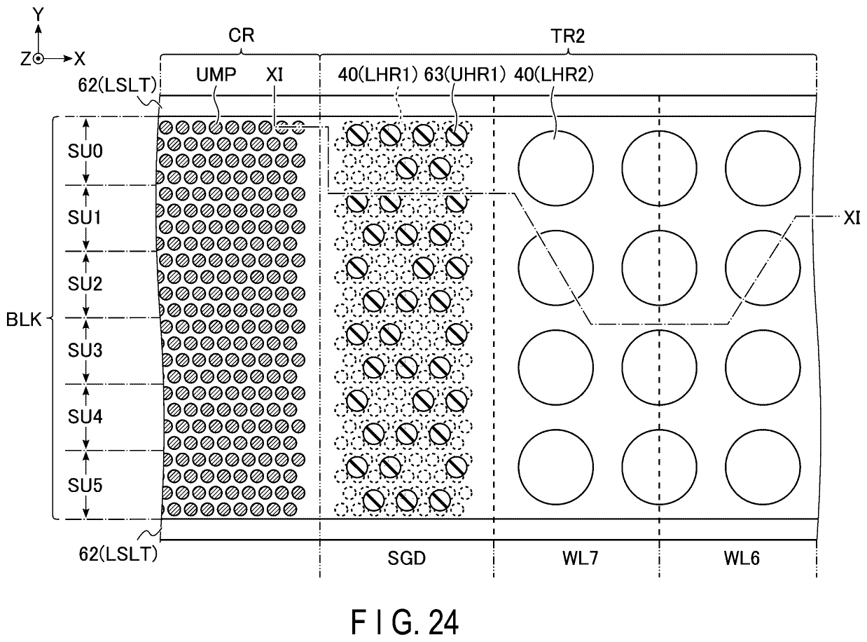

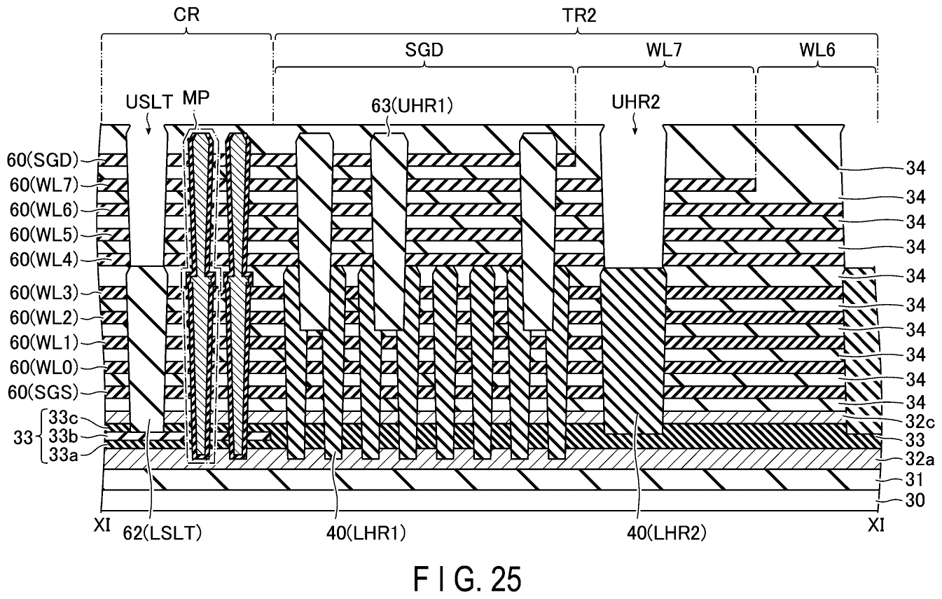

As shown in FIGS. 24 and 25, after the insulating layer 34 is formed to protect the upper surface of the memory pillar MP, a plurality of slits corresponding to the upper members USLT and a plurality of holes corresponding to the upper support pillars UHR2 are collectively processed. A lower end of the slit corresponding to the upper member USLT reaches the sacrificial film 62 filling the lower member LSLT. A lower end of the hole corresponding to the upper support pillar UHR2 reaches the insulator 40 filling the lower support pillar LHR2.

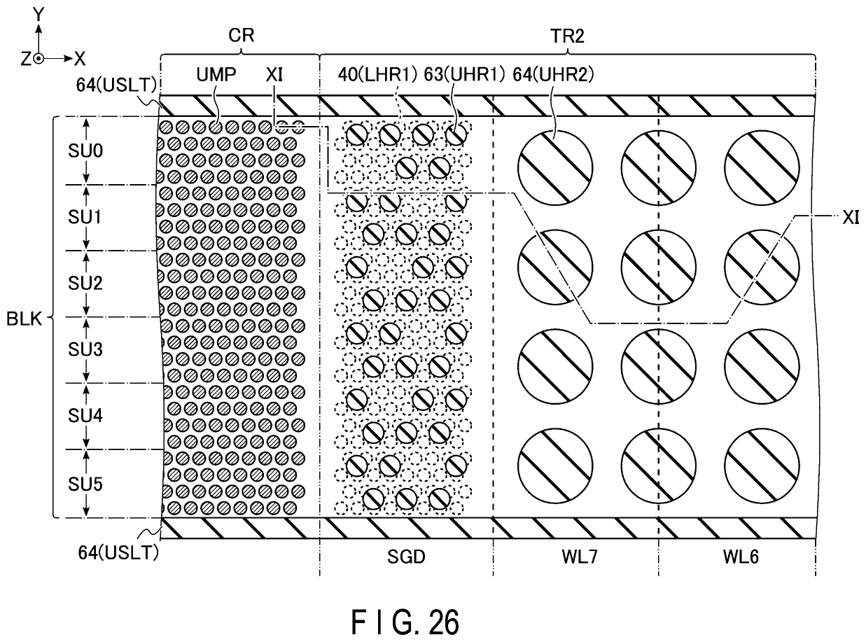

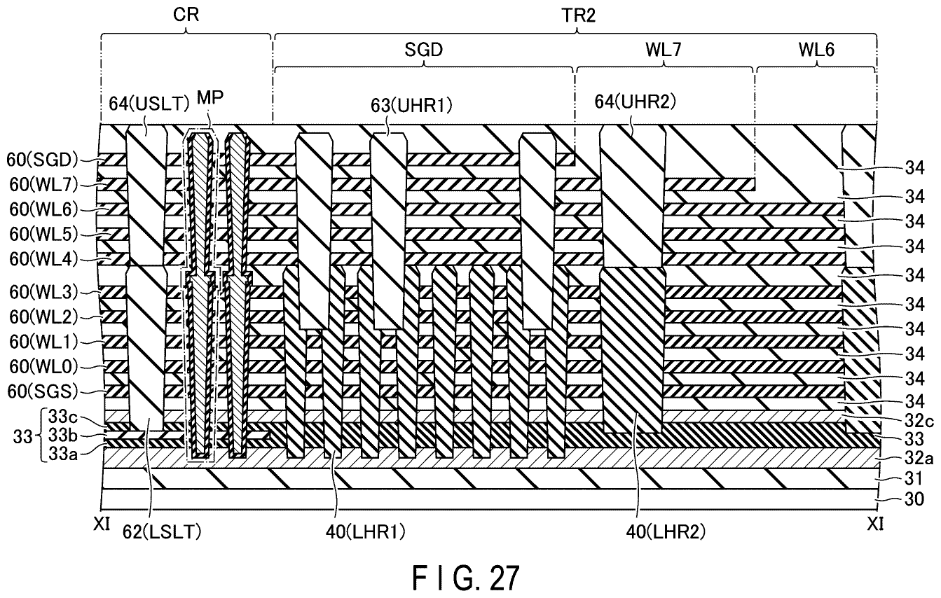

As shown in FIGS. 26 and 27, the slits corresponding to the upper members USLT and holes corresponding to the upper support pillars UHR2 are filled with sacrificial films 64. For example, the sacrificial film 64 contains silicon.

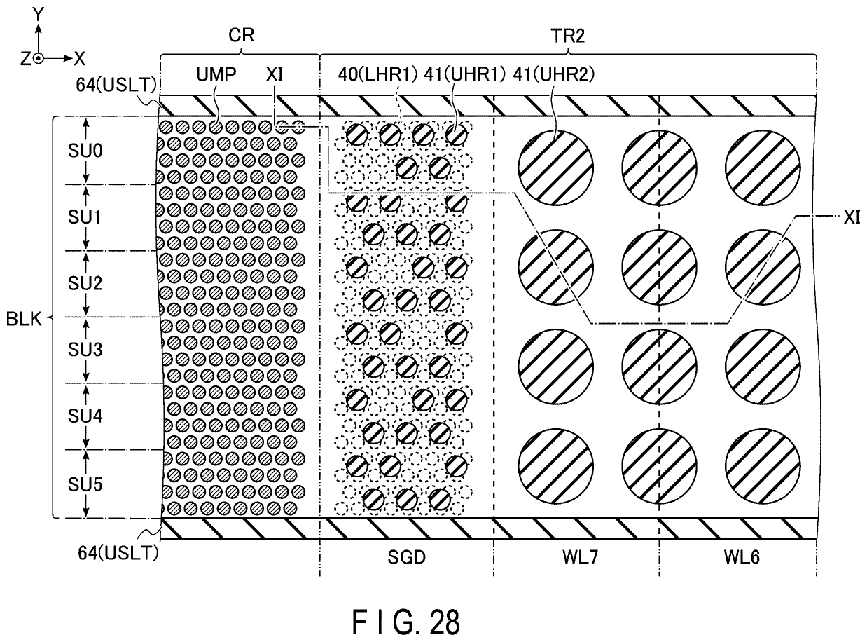

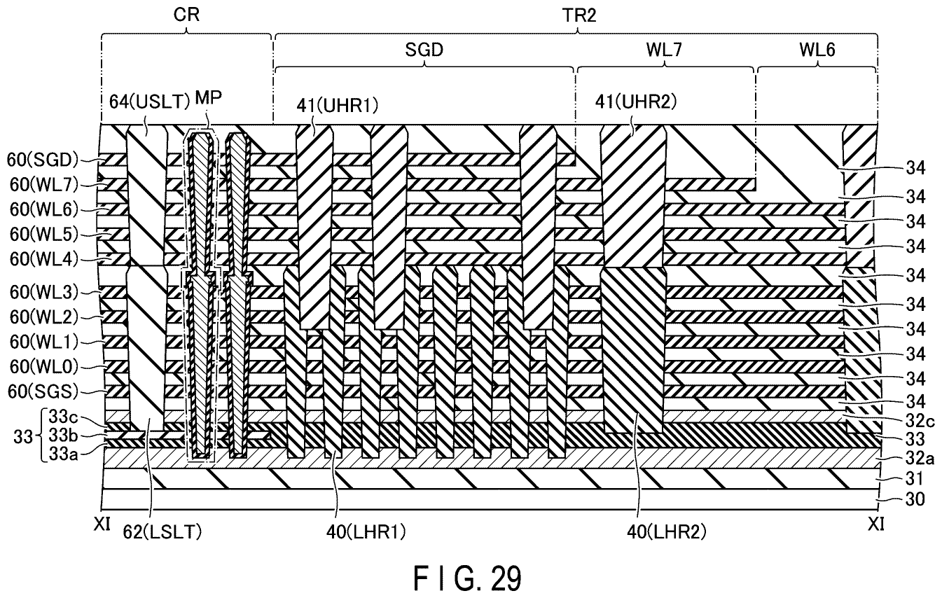

As shown in FIGS. 28 and 29, in the terrace region TR, the sacrificial film 63 in the hole corresponding to the upper support pillar UHR1 and the sacrificial film 64 in the hole corresponding to the upper support pillar UHR2 are removed. Subsequently, the holes corresponding to the upper support pillar UHR1 and the upper support pillar UHR2 are filled with the insulators 41.

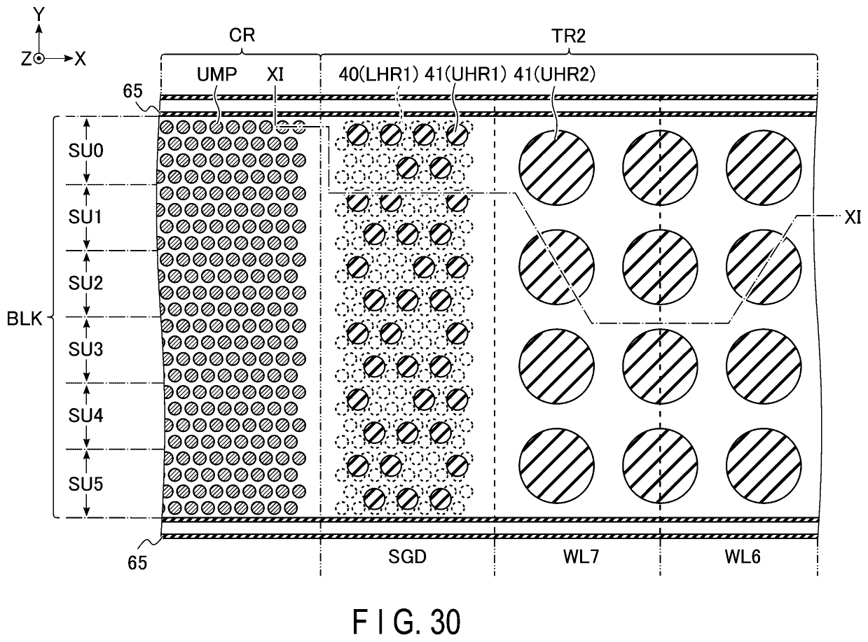

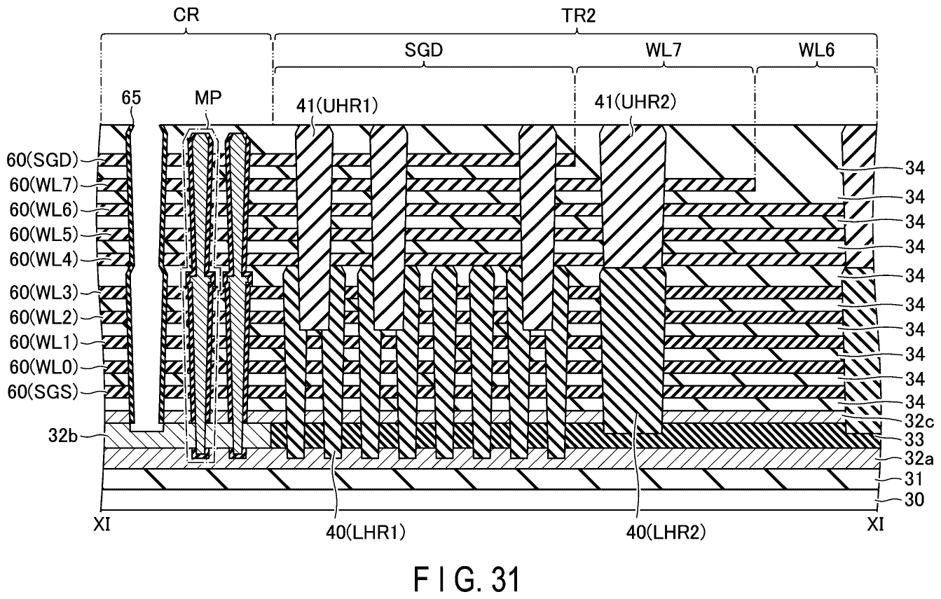

As shown in FIGS. 30 and 31, the sacrificial films 62 and 64 in the slit corresponding to the member SLT are removed to form an insulator 65 on a side surface of the slit. For example, the insulator 65 includes silicon oxide. The insulating layer 33 in the cell region CR is then replaced with the semiconductor layer 32b. At this time, in the memory pillar MP, the block insulating film 51, the charge storage film 52, and the tunnel insulating film 53 on the same layer as the semiconductor layer 32b are removed. More specifically, the insulating layer 33b is removed from a side surface of the slit corresponding to the member SLT is removed by wet etching. For example, if the insulating layer 33b is silicon nitride, wet etching using hot phosphoric acid is executed. The insulating layers 33a and 33c are removed from the side surface of the slit corresponding to the member SLT by wet etching. If, for example, the insulating layers 33a and 33c are silicon oxide, wet etching using hydrofluoric acid is executed. With this process, in the cell region CR where the insulating layer 33b is formed, the insulating layers 33 (33a, 33b, and 33c) are removed. At this time, the block insulating film 51, the charge storage film 52, and the tunnel insulating film 53 positioned on the same layer as the insulating layer 33 are simultaneously removed. The semiconductor layer 32b is then formed to fill the region from which the insulating layer 33 is removed. The semiconductor layer 32b is then formed between the insulating layers 32a and 33c by removing the surplus semiconductor layer 32b on the side surface of the slit corresponding to the member SLT and the insulating layer 34.

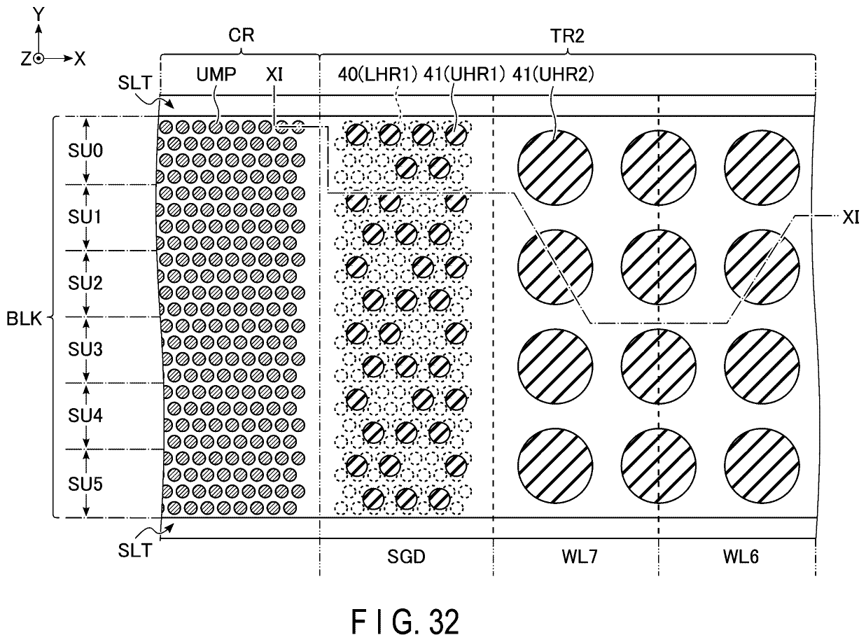

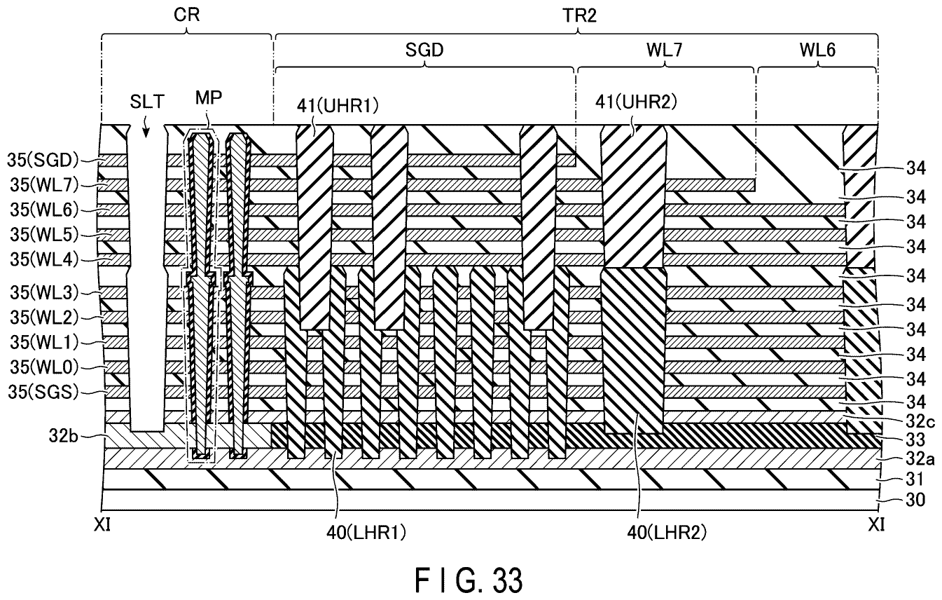

As shown in FIGS. 32 and 33, the sacrificial film 60 is replaced with the interconnect layer 35. More specifically, first of all, the insulator 65 in the slit corresponding to the member SLT is removed. The sacrificial film 60 is then removed from the side surface of the slit corresponding to the member SLT by wet etching. If, for example, the sacrificial film 60 is silicon nitride, wet etching using hot phosphorus acid is executed. The interconnect layer 35 is then formed.

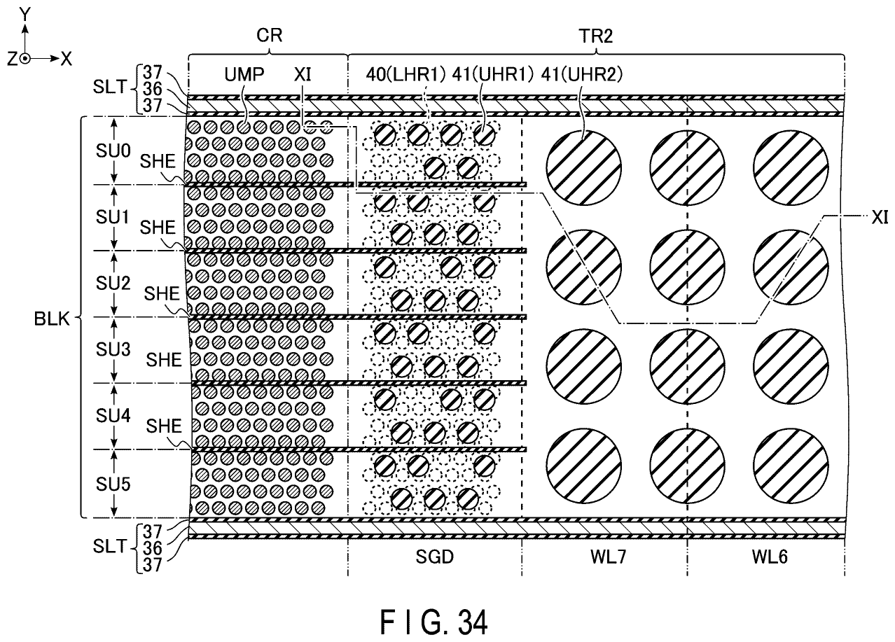

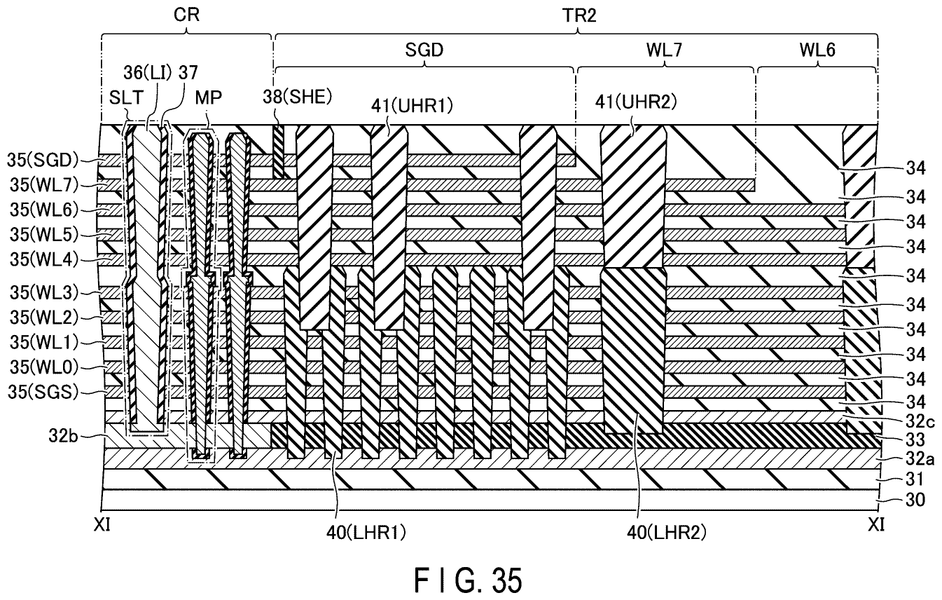

As shown in FIGS. 34 and 35, the member SLT is filled with the conductor 36 and the insulator 37. The member SHE is then formed.

As shown in FIGS. 4 and 5, the contact plugs CC are formed.

### 1.6 Effects of Embodiment

The configuration according to this embodiment can provide the semiconductor memory device 1 that can suppress a decrease in yield. The effects of the embodiment will be described in detail.

For example, in a manufacturing process for a semiconductor memory device, in a case where the interconnect layers 35 functioning as the word lines WL and the select gate lines SGD and SGS are formed by the replace, the removal of the sacrificial films 60 corresponding to the interconnect layers 35 sometimes causes the deflection of the insulating layers 34 due to the air gaps. In order to suppress the deflection of the insulating layers 34, the support pillars HR are provided. For example, the hole corresponding to the support pillar HR is collectively processed with the memory holes LMH and UMH. In order to suppress variations in the etching rates of these holes, the diameter and the pitch of the support pillars HR are set to those similar to the diameter and the pitch of the memory pillars MP. That is, the support pillars HR which are relatively thin and have a small pitch are formed. As the number of interconnect layers 35 stacked on each other increases, the volume of the insulating layers 34 in the terrace region TR increases. This increases the compressive stress by the insulating layers 34 in the terrace region TR. As the compressive stress increases, the support pillar HR distorts and collapses toward the cell region CR or deflection (buckling) occurs in the insulating layer 34 at the time of the removal of the sacrificial film, resulting in a decrease in manufacturing yield. The distortion of the support pillar HR tends to increase toward an end portion of the memory cell array 11. If the size of the support pillar HR is increased to suppress the distortion of the support pillar HR and the deflection of the insulating layer 34, the support pillar and the memory pillar MP cannot be collectively processed, resulting in an increase in the number of steps in a high aspect ratio contact (HARC) process of etching a contact hole with a high aspect ratio. This increases the manufacturing cost. In addition, since the terrace region TR of the select gate line SGD is divided by the members SHE, an excessive increase in the diameter of the support pillar HR makes it impossible to secure a region for the provision of the contact plugs CC. Alternatively, in order to secure the region for the provision of the contact plugs CC, the area of the terrace region TR of the select gate line SGD increases. That is, the chip area increases.

In contrast to this, this embodiment enables the semiconductor memory device 1 to form the plurality of support pillars HR with the terrace regions TR having a plurality of sizes. More specifically, in the terrace region TR of the word lines WL and the select gate line SGS, it is possible to provide the support pillars HR whose diameter and pitch are larger than those of the support pillars HR provided in the terrace region TR of the select gate line SGD. This makes it possible to suppress the distortion of the support pillar HR and the deflection of the insulating layer 34. Accordingly, it is possible to suppress a decrease in the yield of the semiconductor memory device 1.

Furthermore, the configuration according to this embodiment enables the semiconductor memory device 1 to simultaneously process the support pillar HR in the terrace region TR of the word lines WL and the select gate line SGS and the member SLT. This makes it possible to suppress an increase in the number of steps in the HARC process even in a case where the support pillar HR larger in size than the memory pillar MP is formed. Accordingly, it is possible to suppress an increase in the manufacturing cost of the semiconductor memory device 1.

Furthermore, the configuration according to this embodiment enables the semiconductor memory device 1 to make the lower support pillars LHR1 provided in the terrace region TR of the select gate line SGD have a diameter and a pitch similar to those of the memory pillars MP. This makes it possible to collectively process the lower memory pillar LMP and the lower support pillar LHR1 in a manufacturing process for the semiconductor memory device 1.

Furthermore, the configuration according to this embodiment enables the semiconductor memory device 1 to make the upper support pillars UHR1 provided in the terrace region TR of the select gate line SGD have a dimeter and a pitch larger than those of the lower support pillars LHR1 (the memory pillars MP). In this case, a lower end of the upper support pillar UHR1 can be provided at a height position lower than an upper surface of the lower support pillar LHR1. This makes it possible to suppress the distortion of the support pillar HR and the deflection of the insulating layer 34. In addition, in a manufacturing process for the semiconductor memory device 1, the upper memory pillar UMP and the upper support pillar UHR1 can be collectively processed. This makes it possible to suppress an increase in the number of steps in the HARC process.

Furthermore, the configuration according to this embodiment enables the semiconductor memory device 1 to make the upper support pillars UHR1 have a diameter and a pitch about twice those of the lower support pillars LHR1. This makes it possible to secure a region for the contact plugs CC in the terrace region TR of the select gate line SGD. Accordingly, it is possible to suppress an increase in chip area.

### 2. Second Embodiment

The second embodiment will be described next. The second embodiment will exemplify a support pillar HR size and a layout which are different from those in the first embodiment. Differences from the first embodiment will be mainly described below.

### 2.1 Planar Layout of Memory Cell Array

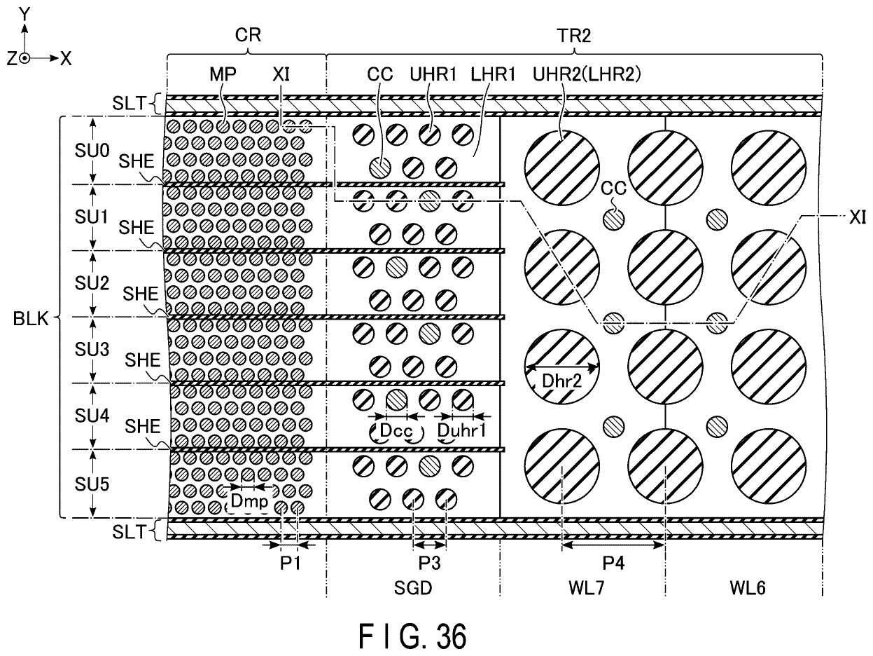

An example of a planar layout of a memory cell array 11 will be described first with reference to FIG. 36. FIG. 36 is a plan view showing an example of a planar layout of a memory cell array 11.

As shown in FIG. 36, a planar layout of a cell region CR is the same as that in FIG. 4 according to the first embodiment.

In this embodiment, in a terrace region TR of a select gate line SGD, lower support pillars LHR1 and upper support pillars UHR1 are arranged in a staggered pattern. A diameter and a layout of the upper surfaces of the lower support pillars LHR1 are the same as those of the upper surfaces of the upper support pillars UHR1. For example, a diameter Dlhr1 of the lower support pillar LHR1, a diameter Duhr1 of the upper support pillar UHR1, and a diameter Dcc of a contact plug CC are almost equal to each other. The diameter Dlhr1 of the lower support pillar LHR1, the diameter Duhr1 of the upper support pillar UHR1, and the diameter Dcc of the contact plug CC are larger than a diameter Dmp of a memory pillar MP. The upper support pillar UHR1 is provided on the lower support pillar LHR1.

The diameters and layouts of lower support pillars LHR2, upper support pillars UHR2, and contact plugs CC in the terrace region TR of word lines WL and a select gate line SGS are the same as those in FIG. 4 according to the first embodiment.

### 2.2 Cross-Sectional Configuration of Memory Cell Array

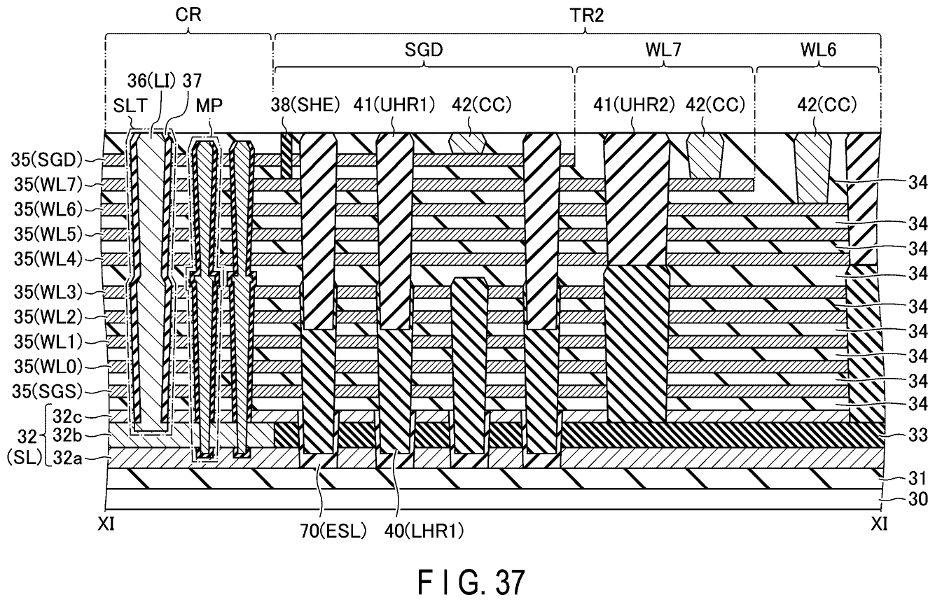

An example of a cross-sectional configuration of the memory cell array 11 will be described next with reference to FIG. 37. FIG. 37 is a cross-sectional view of the memory cell array 11 taken along line XI-XI in FIG. 36. In the example shown in FIG. 37, to simplify explanation, the illustrations of conductors (contact plugs, interconnect layers, bit lines BL, or the like) provided on the memory pillars MP, the contact plugs CC, and the member SLT are omitted.

As shown in FIG. 37, structures of the member SLT, the memory pillar MP, the lower support pillar LHR2, the upper support pillar UHR2, and the contact plug CC are the same as those in FIG. 5 according to the first embodiment.

In the terrace region TR of the select gate line SGD, an etch stop layer ESL is provided under the lower support pillar LHR1. The etch stop layer ESL functions as a stopper at the time of processing a hole corresponding to the lower support pillar LHR1. The diameter Dlhr1 of the lower support pillar LHR1 in this embodiment is larger than the diameter Dmp of the memory pillar MP. For this reason, in a case where a hole corresponding to the lower support pillar LHR1 and a memory hole LMH are collectively processed, the etching rate of the hole corresponding to the lower support pillar LHR1 becomes higher than the etching rate of the memory hole LMH. However, providing the etch stop layer ESL can prevent the hole corresponding to the lower support pillar LHR1 from extending through a semiconductor layer 32. The etch stop layer ESL is filled with a member 70. The member 70 is preferably a material that can obtain a sufficient etching selection ratio at the time of processing the lower support pillar LHR1. The member 70 may contain, for example, carbon or a metal.

As in the first embodiment, the upper support pillar UHR1 passes through, for example, seven interconnect layers 35 respectively functioning as word lines WL2 to WL7 and the select gate line SGD and insulating layers 34. A lower end of the upper support pillar UHR1 is positioned between, for example, the interconnect layer 35 functioning as the word line WL2 and the interconnect layer 35 functioning as the word line WL1. Accordingly, the lower end of the upper support pillar UHR1 is positioned on a lower side (the side near the semiconductor layer 32) of the one or more interconnect layers 35 relative to an upper end of the lower support pillar LHR1. The upper support pillar UHR1 extends (passes) through part of the lower support pillar LHR1 which is located near an upper end and at least one of the interconnect layers 35 of the lower tier.

### 2.3 Method of Manufacturing Memory Cell Array

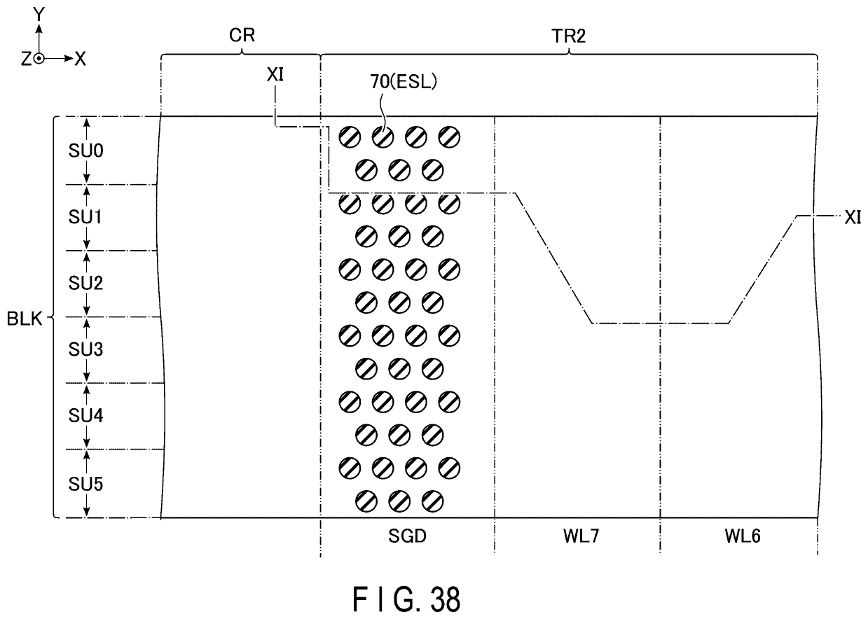

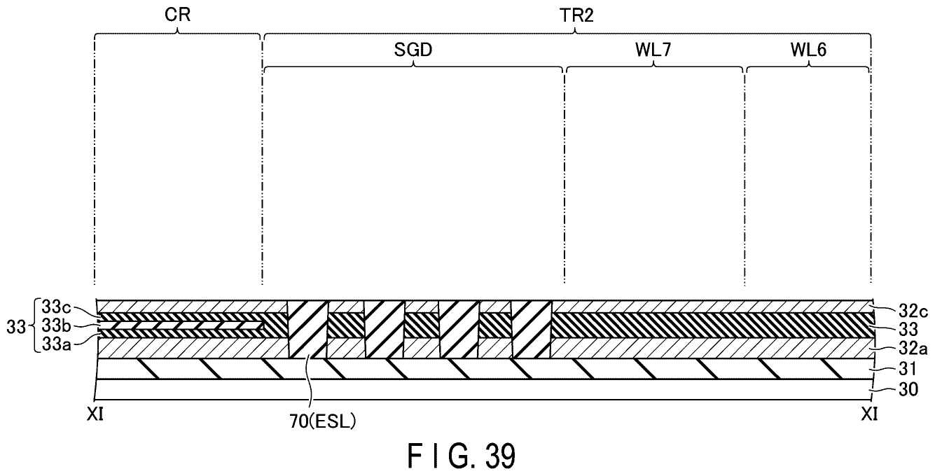

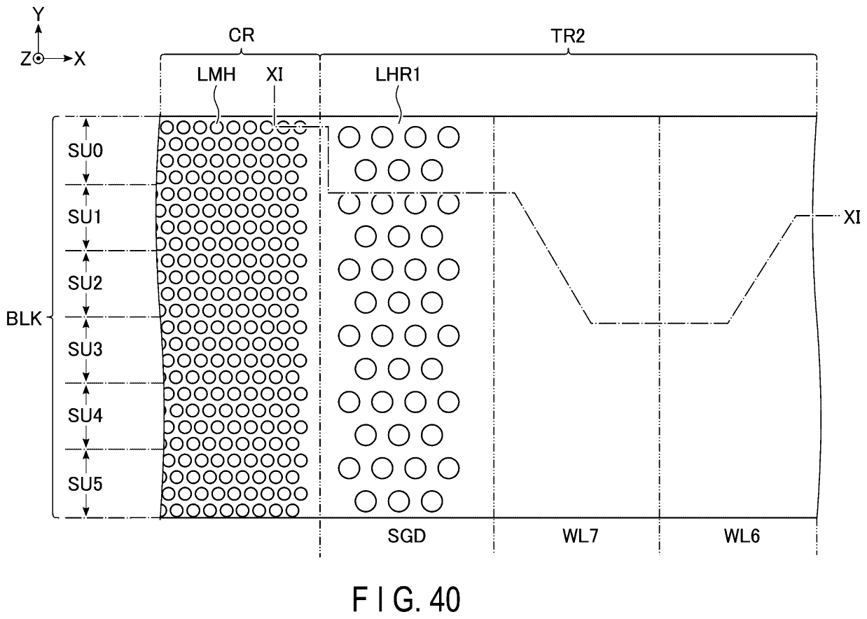

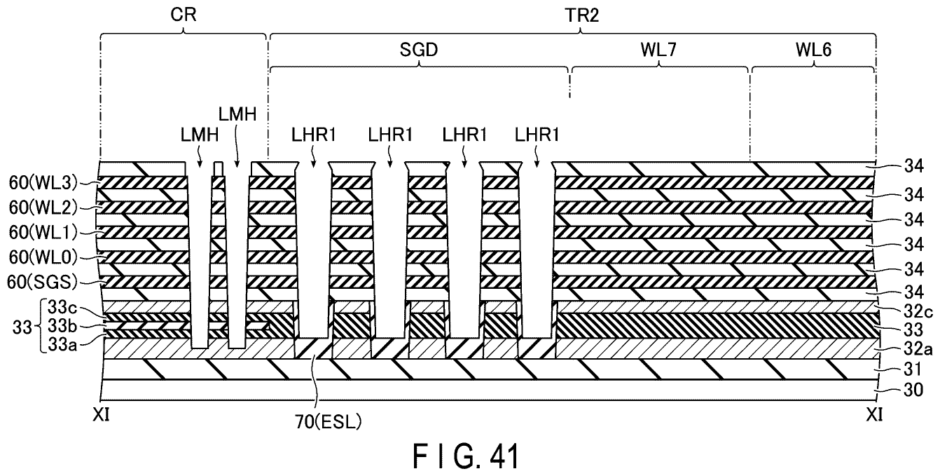

An example of a method of manufacturing the memory cell array 11 will be described next with reference to FIGS. 38, 39, 40, and 41. FIGS. 38 and 40 are plan views of the memory cell array 11 showing a manufacturing process for the memory cell array 11. FIGS. 39 and 41 are cross-sectional views of the memory cell array 11 showing a manufacturing process for the memory cell array 11. In the following description, focus is placed on a manufacturing process for the etch stop layer ESL.

First of all, as shown in FIGS. 38 and 39, after a semiconductor layer 32c is formed following a similar procedure to that in the first embodiment, the member 70 functioning as the etch stop layer ESL is formed. Note that the diameter of an upper surface of the member 70 is only required to be larger than a diameter of a lower end of the lower support pillar LHR1. In the example shown in FIG. 39, the member 70 is formed after the semiconductor layer 32c is formed. If, however, the member 70 is an insulator, the member 70 may be formed after the insulating layer 34 is formed on the semiconductor layer 32c. In addition, a lower end of the member 70 may or may not reach the insulating layer 31.

Subsequently, as shown in FIGS. 40 and 41, the six insulating layers 34 and five sacrificial films 60 are alternately stacked one by one. In this state, the memory holes LMH corresponding to a lower memory pillar LMP and a joint portion JT and holes corresponding to the lower support pillar LHR1 are formed. The lower end of the hole corresponding to the lower support pillar LHR1 is in the etch stop layer ESL. As described above, the memory pillar MP and the lower support pillar LHR1 having a diameter different from that of the memory pillar MP can be collectively processed. The subsequent manufacturing steps are the same as those in the first embodiment.

### 2.4 Effects of Embodiment

The configuration according to this embodiment can obtain effects similar to those in the first embodiment.

Furthermore, the configuration according to this embodiment enables a semiconductor memory device 1 to provide the etch stop layer ESL at the bottom portion of the lower support pillar LHR1 in the terrace region TR of the select gate line SGD. This makes it possible to control the depth of the hole corresponding to the lower support pillar LHR1. Even if the size of the lower support pillar LHR1 is set to be larger than the size of the memory pillar MP, the memory pillar MP and the lower support pillar LHR1 having a diameter different from that of the memory pillar MP can be collectively processed.

Furthermore, the configuration according to this embodiment enables the semiconductor memory device 1 to make the lower support pillars LHR1 and the upper support pillars UHR1 provided in the terrace region TR of the select gate line SGD have a larger diameter and pitch than the memory pillars MP. This makes it possible to suppress the distortion of the support pillar HR and the deflection of the insulating layer 34.

### 3. Third Embodiment

The third embodiment will be described next. The third embodiment will exemplify a support pillar HR size and layout different from those in the first and second embodiments. Differences from the first and second embodiments will be mainly described below.

### 3.1 Planar Layout of Memory Cell Array

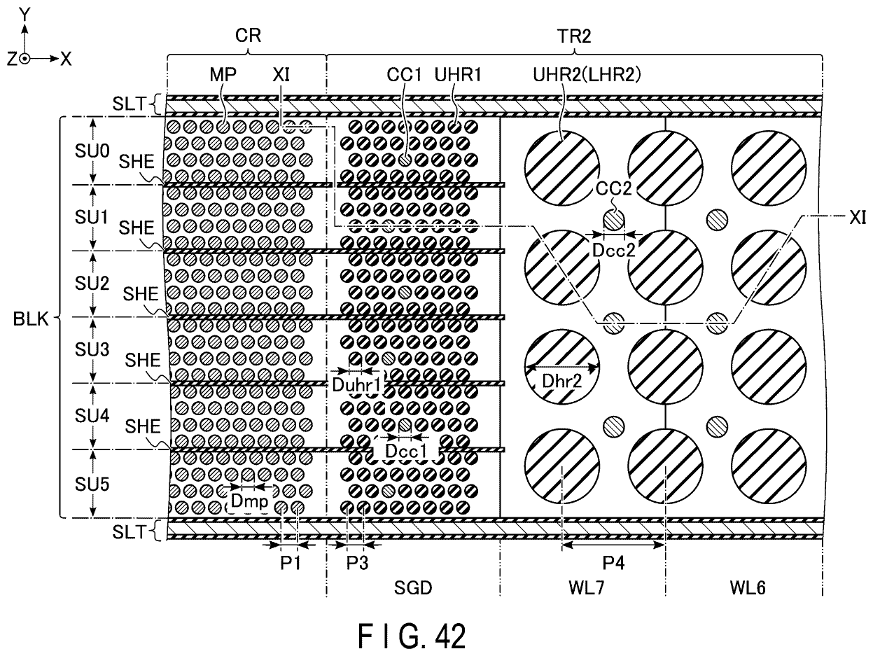

An example of a planar layout of a memory cell array 11 will be described first with reference to FIG. 42. FIG. 42 is a plan view showing an example of a planar layout of the memory cell array 11.

As shown in FIG. 42, a planar layout of a cell region CR is the same as that in FIG. 4 according to the first embodiment.

In this embodiment, in a terrace region TR of a select gate line SGD, lower support pillars LHR1, upper support pillars UHR1, and contact plugs CC having the same size as a diameter Dmp of a memory pillar MP are provided. If the contact plugs CC provided in the terrace region TR of the select gate line SGD are distinguished, they are written as “contact plugs CC1”.

The diameter Dmp of the memory pillar MP, a diameter Dlhr1 of the lower support pillar LHR1, a diameter Duhr1 of the upper support pillar UHR1, and the diameter Dcc1 of the contact plug CC1 are almost equal to each other. The planar layout of the memory pillars MP is almost identical to planar layouts of the lower support pillars LHR1 and the upper support pillars UHR1. Accordingly, a pitch P1 of the memory pillars MP, a pitch P2 of the lower support pillars LHR1, and a pitch P3 of the upper support pillars UHR1 are almost equal to each other. The upper support pillars UHR1 and the contact plugs CC1 are formed on the lower support pillars LHR1.

In this embodiment, a diameter Dcc2 of the contact plugs CC (to be written as “contact plugs CC2” hereinafter) in the terrace region TR of word lines WL and a select gate line SGS is larger than a diameter Dcc1 of the contact plugs CC1 in the terrace region TR of the select gate line SGD and smaller than a diameter Dhr2 of lower support pillars LHR2 and upper support pillars UHR2. A planar layout of the terrace region TR of the word lines WL and the select gate line SGS is the same as that shown in FIG. 4 according to the first embodiment.

In this embodiment, the structure of the support pillars HR (LHR1 and UHR1) provided in the terrace region TR of the select gate line SGD may be the same as that of the memory pillars MP. That is, the support pillar HR provided in the terrace region TR of the select gate line SGD may have a structure filled with a block insulating film 51, a charge storage film 52, a tunnel insulating film 53, a semiconductor film 54, and a core film 55.

### 3.2 Cross-Sectional Configuration of Memory Cell Array

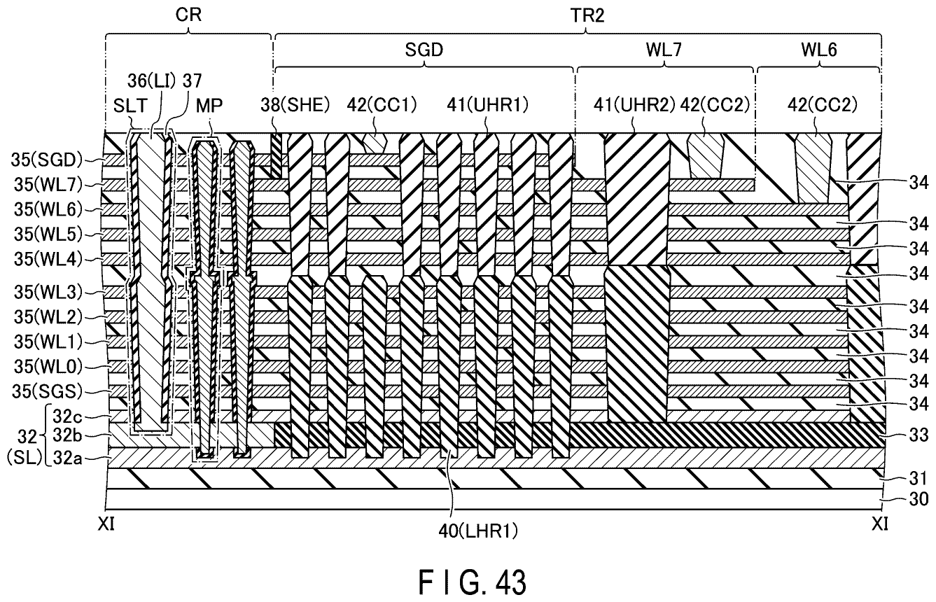

An example of a cross-sectional configuration of the memory cell array 11 will be described next with reference to FIG. 43. FIG. 43 is a cross-sectional view of the memory cell array 11 taken along line XI-XI in FIG. 42. In the example shown in FIG. 43, to simplify explanation, the illustrations of conductors (contact plugs, interconnect layers, bit lines BL, or the like) provided on the memory pillars MP, the contact plugs CC, and the member SLT are omitted.

As shown in FIG. 43, structures of the member SLT, the memory pillar MP, the lower support pillar LHR2, the upper support pillar UHR2, and the contact plug CC2 are the same as those in FIG. 5 according to the first embodiment.

In the terrace region TR of the select gate line SGD, the diameter Duhr1 of the upper support pillar UHR1 is almost equal to the diameter Dmp of the memory pillar MP. For this reason, the etching rate of the memory hole UMH corresponding to the upper memory pillar UMP is almost equal to the etching rate of the hole corresponding to the upper support pillar UHR1. Accordingly, if a lower surface of the upper support pillar UHR1 is provided on an upper surface of the lower support pillar LHR1, the upper support pillar UHR1 hardly extends through the upper end of the lower support pillar LHR1. In other words, in a manufacturing process for the semiconductor memory device 1, the upper support pillar UHR1 hardly extends through the upper end of the lower support pillar LHR1 as long as the lower surface of the upper support pillar UHR1 comes off the upper surface of the lower support pillar LHR1 upon occurrence of misalignment between the upper support pillar UHR1 and the lower support pillar LHR1. If, however, the lower surface of the upper support pillar UHR1 comes off the upper surface of the lower support pillar LHR1, that is, misalignment has occurred between the upper support pillar UHR1 and the lower support pillar LHR1, the upper support pillar UHR1 can extend through the upper end of the lower support pillar LHR1.

### 3.3 Effects of Embodiment

The configuration according to this embodiment can obtain effects similar to those in the first embodiment.

Furthermore, the configuration according to this embodiment enables a semiconductor memory device 1 to make the lower support pillars LHR1, the upper support pillars UHR1, and the contact plugs CC1 provided in the terrace region TR of the select gate line SGD have the same diameter and pitch as those of the memory pillars MP.

### 4. Modification

The semiconductor memory device according to the above embodiment includes a first semiconductor layer (32) provided above a substrate (30), a plurality of first interconnect layers (35, SGS, WL0-WL3) stacked apart from each other in a first direction (Z direction) above the first semiconductor layer, a plurality of second interconnect layers (35, WL4-WL7) stacked and separated from each other in the first direction above the plurality of first interconnect layers, a third interconnect layer (35, SGD) provided above the plurality of second interconnect layers, a third memory pillar (MP) including a first memory pillar (LMP) passing through the plurality of first interconnect layers in the first direction and a second memory pillar (UMP) provided on the first memory pillar and passing through the plurality of second interconnect layers and the third interconnect layer in the first direction, a first region (TR of SGD) where a first contact plug (CC) is provided on the third interconnect layer, a second region (TR of SGS, WL0-WL7) where a second contact plug (CC) is provided on each of the plurality of second interconnect layers, a first support pillar (LHR1) passing through the plurality of first interconnect layers in the first region, a second support pillar (UHR1) passing through at least the plurality of second interconnect layers and the third interconnect layer in the first region, a third support pillar (LHR2) passing through at least one of the plurality of first interconnect layers and having a larger diameter than the first support pillar and the second support pillar in the second region, and a fourth support pillar (UHR2) provided on the third support pillar and having a larger diameter than the first support pillar and the second support pillar in the second region.

The configuration according to each embodiment described above can provide a semiconductor memory device that can improve the yield.

In addition to the above embodiments, various modifications are applicable.

In addition, “coupling” in the above embodiments includes a state in which constituent elements are coupled indirectly via other elements like a transistor or a resistor.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first semiconductor layer provided above a substrate;
a plurality of first interconnect layers stacked apart from each other in a first direction above the first semiconductor layer;
a plurality of second interconnect layers stacked and separated from each other in the first direction above the plurality of first interconnect layers;
a third interconnect layer provided above the plurality of second interconnect layers;
a third memory pillar including a first memory pillar passing through the plurality of first interconnect layers in the first direction and a second memory pillar provided on the first memory pillar and passing through the plurality of second interconnect layers and the third interconnect layer in the first direction;
a first region where a first contact plug is provided on the third interconnect layer;
a second region where a second contact plug is provided on each of the plurality of second interconnect layers;
a first support pillar passing through the plurality of first interconnect layers in the first region;
a second support pillar passing through at least the plurality of second interconnect layers and the third interconnect layer in the first region;
a third support pillar passing through at least one of the plurality of first interconnect layers and having a larger diameter than the first support pillar and the second support pillar in the second region; and
a fourth support pillar provided on the third support pillar and having a larger diameter than the first support pillar and the second support pillar in the second region.

2. The device according to claim 1, wherein a diameter of the first support pillar and a pitch of the first support pillars adjacent to each other are equal to a diameter of the third memory pillar and a pitch of the third memory pillars adjacent to each other.

3. The device according to claim 2, wherein a diameter of the second support pillar and a pitch of the second support pillars adjacent to each other are larger than the diameter of the first support pillar and the pitch of the first support pillars.

4. The device according to claim 2, wherein a diameter of the second support pillar and a pitch of the second support pillars adjacent to each other are equal to the diameter of the first support pillar and the pitch of the first support pillars.

5. The device according to claim 3, wherein the pitch of the second support pillars is twice the pitch of the first support pillars.

6. The device according to claim 1, wherein the second support pillar passes through at least one of the plurality of first interconnect layers and is in contact with the first support pillar.

7. The device according to claim 6, wherein a central axis of the second support pillar is arranged at a position different from a central axis of the first support pillar in a second direction intersecting the first direction and a third direction intersecting the first direction and the second direction.

8. The device according to claim 1, wherein one end of the first memory pillar and one end of the first support pillar reach into the first semiconductor layer.

9. The device according to claim 1, further comprising an etch stop layer provided on the same layer as the first semiconductor layer,
wherein the first support pillar is provided on the etch stop layer,
the second support pillar is provided on the first support pillar, and
a diameter of the first support pillar and a pitch of the first support pillars adjacent to each other and a diameter of the second support pillar and a pitch of the second support pillars adjacent to each other are larger than a diameter of the third memory pillar and a pitch of the third memory pillars adjacent to each other.

10. The device according to claim 9, wherein a diameter of an upper surface of the etch stop layer is larger than a diameter of a lower surface of the first support pillar.

11. The device according to claim 1, wherein the second support pillar passes through at least one of the plurality of first interconnect layers and reaches the first support pillar.

12. The device according to claim 1, wherein a diameter of the first contact plug is smaller than a diameter of the second contact plug.

13. The device according to claim 11, wherein the diameter of the first contact plug is equal to larger than a diameter of the third memory pillar.

14. The device according to claim 1, wherein the third memory pillar includes a second semiconductor film extending in the first direction and coupled to the first semiconductor layer and a charge storage film.

15. The device according to claim 1, wherein the first support pillar and the third support pillar are electrically uncoupled to the first semiconductor layer and the plurality of first interconnect layers, and
the second support pillar and the fourth support pillar are electrically uncoupled to the plurality of second interconnect layer and the third interconnect layer.
